(19) United States
(12) Patent Application Publication
(10) Pub. No.: US 2012/0049168 A1
(43) Pub. Date: Mar. 1, 2012

(54) Cross-Linked Charge Transport Layer Containing an Additive Compound

(75) Inventors: Michael INBASEKARAN, Lambertville, NJ (US); Kwang-Ohk CHEON, Holland, PA (US); Chuanjun XIA, Lawrenceville, NJ (US); Siddharth Harikrishna MOHAN, Plainsboro, NJ (US)

(73) Assignee: UNIVERSAL DISPLAY CORPORATION, Ewing, NJ (US)

(21) Appl. No.: 13/163,933

(22) Filed: Jun. 20, 2011

Related U.S. Application Data
(63) Continuation-in-part of application No. 12/872,342, filed on Aug. 31, 2010.

(51) Int. Cl. H01L 51/54; H01B 1/12; H01L 51/56

(52) U.S. Cl. 257/40; 438/46; 252/500; 257/E51.027

(57) ABSTRACT

Organic electronic devices comprising an improved charge transport layer. The charge transport layer comprises a covalently cross-linked host matrix. The covalently cross-linked matrix comprises a charge transport compound as molecular subunits that are cross-linked to each other. The charge transport layer further comprises a second charge transport compound as an additive, which may be a small molecule, or a polymer, or a mixture of both. The charge transport layer may be a hole transport layer. The charge transport compound for the additive may be an arylamine compound, such as NPD.

### CROSS-REFERENCES

This application claims priority to and is a continuation-in-part of U.S. application Ser. No. 12/872,342 filed on 31 Aug. 2010, which is incorporated by reference herein.

### FIELD OF THE INVENTION

The present invention relates to organic light emitting devices (OLEDs), and more specifically to organic layers used in such devices.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules. In general, a small molecule has a well-defined chemical formula with a single molecular weight, whereas a polymer has a chemical formula and a molecular weight that may vary from molecule to molecule. As used herein, “organic” includes metal complexes of hydrocarbyl and heteroatom-substituted hydrocarbyl ligands.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

OLED devices are generally (but not always) intended to emit light through at least one of the electrodes, and one or more transparent electrodes may be useful in an organic opto-electronic devices. For example, a transparent electrode material, such as indium tin oxide (ITO), may be used as the bottom electrode. A transparent top electrode, such as disclosed in U.S. Pat. Nos. 5,703,436 and 5,707,745, which are incorporated by reference in their entireties, may also be used. For a device intended to emit light only through the bottom electrode, the top electrode does not need to be transparent, and may be comprised of a thick and reflective metal layer having a high electrical conductivity. Similarly, for a device intended to emit light only through the top electrode, the bottom electrode may be opaque and/or reflective. Where an electrode does not need to be transparent, using a thicker layer may provide better conductivity, and using a reflective electrode may increase the amount of light emitted through the other electrode, by reflecting light back towards the transparent electrode. Fully transparent devices may also be fabricated, where both electrodes are transparent. Side emitting OLEDs may also be fabricated, and one or both electrodes may be opaque or reflective in such devices.

As used herein, “top” means furthest away from the substrate, while “bottom” means closest to the substrate. For example, for a device having two electrodes, the bottom electrode is the electrode closest to the substrate, and is generally the first electrode fabricated. The bottom electrode has two surfaces, a bottom surface closest to the substrate, and a top surface further away from the substrate. Where a first layer is described as “disposed over” a second layer, the first layer is disposed further away from substrate. There may be other layers between the first and second layer, unless it is specified that the first layer is “in physical contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

### SUMMARY

The present invention provides an improved charge transport layer for an organic electronic device. In one embodiment, the present invention provides an organic electronic device comprising: a first electrode; a second electrode; and a charge transport layer between the first electrode and the second electrode, the charge transport layer comprising: (a) a covalently cross-linked host matrix comprising a first organic charge transport compound as molecular subunits of the cross-linked host matrix; and (b) a second organic charge transport compound that is a polymer compound that transports the same type of charge as the cross-linked host matrix.

In another embodiment, the present invention provides an organic electronic device comprising: a first electrode; a second electrode; a hole transport layer between the first electrode and the second electrode, the hole transport layer comprising: (a) a covalently cross-linked host matrix comprising a first organic hole transport compound as molecular subunits of the cross-linked host matrix; and (b) a second organic hole transport compound that transports the same type of charge as the cross-linked host matrix.

In another embodiment, the present invention provides a method of making an organic electronic device, comprising: providing a first electrode disposed over a substrate; depositing over the first electrode, a solution comprising: (a) a first organic charge transport compound having one or more cross-linkable reactive groups, and (b) a second organic charge transport compound that transports the same type of charge as the first charge transport compound; forming a first organic layer by cross-linking the first charge transport compound; forming a second organic layer over the first organic layer; and forming a second electrode over the second organic layer.

In some cases, the second charge transport compound is a polymer compound. In some cases, the second charge transport compound is a small molecule compound. In some cases, the first charge transport compound and the second charge compound are both hole transport compounds. In some cases, the organic electronic device is an organic light-emitting device and the second organic layer is an emissive layer. In some cases for an organic light-emitting device, the emissive layer comprises a phosphorescent emitting dopant. In some cases, the emissive layer comprises a fluorescent emitting compound. In some cases, the second organic layer is formed directly on the first organic layer, and the step of forming the second organic layer is performed by solution deposition.

In some cases, the first charge transport compound is an arylamine compound. In some cases, the amount of the second charge transport compound in the solution is 5-30 wt % relative to the first charge transport compound. In some cases, the first organic layer is a hole transport layer, and the method further comprises: forming over the first electrode, a cross-linked hole injection layer comprising a cross-linked organometallic iridium complex; wherein the solution for the hole transport layer is deposited directly on the cross-linked hole injection layer. In some cases, the cross-linked hole injection layer is formed by depositing over the first electrode, a solution comprising an organometallic iridium complex having one or more cross-linkable reactive groups, and cross-linking the organometallic iridium complex to form the cross-linked hole injection layer.

In another embodiment, the present invention provides a liquid composition comprising: a solvent; a first organic charge transport compound having one or more cross-linkable reactive groups; and a second organic charge transport compound that transports the same type of charge as the first charge transport compound. Liquid compositions of the present invention can be used for making solution-deposited layers in an organic electronic device.

In some cases, the second charge transport compound is a polymer compound. In some cases, wherein the polymer compound includes triarylamine moieties. In some cases, the polymer compound includes carbazole moieties. In some cases, the polymer compound is poly(N-vinylcarbazole).

In some cases, the second charge transport compound is a small molecule compound. In some cases, the first charge transport compound and the second charge compound are both hole transport compounds. In some cases, the first charge transport compound is an arylamine compound. In some cases, the amount of the second charge transport compound is 5-30 wt % relative to the first charge transport compound. In some cases, the second hole transport compound includes triarylamine moieties.

### BRIEF DESCRIPTION OF THE DRAWINGS

FIG. 1 shows an organic light emitting device having separate electron transport, hole transport, and emissive layers, as well as other layers.

FIG. 2 shows an inverted organic light emitting device that does not have a separate electron transport layer.

FIG. 3 shows a plot of luminance as a function of time for example Devices 1 and 2.

FIG. 4 shows a plot of luminance efficiency as a function of luminance for example Devices 1 and 2.

FIG. 5 shows an example of how the HOMO energy level of a hole transport layer may be aligned relative to other layers in an organic light-emitting device.

FIGS. 6A-6L show example compounds that may be suitable for use as a polymer additive in the charge transport layer of the present invention.

FIG. 7 shows a plot of luminance as a function of time for example Devices 5 and 6.

### DETAILED DESCRIPTION OF THE INVENTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 1, 4-6 (1999) (“Baldo-II”), which are incorporated by reference in their entireties. Phosphorescence may be referred to as a “forbidden” transition because the transition requires a change in spin states, and quantum mechanics indicates that such a transition is not favored. As a result, phosphorescence generally occurs in a time frame exceeding at least 10 nanoseconds, and typically greater than 100 nanoseconds. If the natural radiative lifetime of phosphorescence is too long, triplets may decay by a non-radiative mechanism, such that no light is emitted. Organic phosphorescence is also often observed in molecules containing heteroatoms with unshared pairs of electrons at very low temperatures. 2,2′-bipyridine is such a molecule. Non-radiative decay mechanisms are typically temperature dependent, such that an organic material that exhibits phosphorescence at liquid nitrogen temperatures typically does not exhibit phosphorescence at room temperature. But, as demonstrated by Baldo, this problem may be addressed by selecting phosphorescent compounds that do phosphoresce at room temperature. Representative emissive layers include doped or un-doped phosphorescent organometallic materials such as disclosed in U.S. Pat. Nos. 6,303,238 and 6,310,360; U.S. Patent Application Publication Nos. 2002/0034656; 2002/0182441; 2003/0072964; and PCT publication WO 02/074015.

Generally, the excitons in an OLED are believed to be created in a ratio of about 3:1, i.e., approximately 75% triplets and 25% singlets. See, Adachi et al., “Nearly 100% Internal Phosphorescent Efficiency In An Organic Light Emitting Device,” J. Appl. Phys., 90, 5048 (2001), which is incorporated by reference in its entirety. In many cases, singlet excitons may readily transfer their energy to triplet excited states via “intersystem crossing,” whereas triplet excitons may not readily transfer their energy to singlet excited states. As a result, 100% internal quantum efficiency is theoretically possible with phosphorescent OLEDs. In a fluorescent device, the energy of triplet excitons is generally lost to radiationless decay processes that heat-up the device, resulting in much lower internal quantum efficiencies. OLEDs utilizing phosphorescent materials that emit from triplet excited states are disclosed, for example, in U.S. Pat. No. 6,303,238, which is incorporated by reference in its entirety.

Phosphorescence may be preceded by a transition from a triplet excited state to an intermediate non-triplet state from which the emissive decay occurs. For example, organic molecules coordinated to lanthanide elements often phosphoresce from excited states localized on the lanthanide metal. However, such materials do not phosphoresce directly from a triplet excited state but instead emit from an atomic excited state centered on the lanthanide metal ion. The europium diketonate complexes illustrate one group of these types of species.

Phosphorescence from triplets can be enhanced over fluorescence by confining, preferably through bonding, the organic molecule in close proximity to an atom of high atomic number. This phenomenon, called the heavy atom effect, is created by a mechanism known as spin-orbit coupling. Such a phosphorescent transition may be observed from an excited metal-to-ligand charge transfer (MLCT) state of an organometallic molecule such as tris(2-phenylpyridine)iridium(III).

As used herein, the term “triplet energy” refers to an energy corresponding to the highest energy feature discernable in the phosphorescence spectrum of a given material. The highest energy feature is not necessarily the peak having the greatest intensity in the phosphorescence spectrum, and could, for example, be a local maximum of a clear shoulder on the high energy side of such a peak.

The term “organometallic” as used herein is as generally understood by one of ordinary skill in the art and as given, for example, in “Inorganic Chemistry” (2nd Edition) by Gary L. Miessler and Donald A. Tan, Prentice Hall (1998). Thus, the term organometallic refers to compounds which have an organic group bonded to a metal through a carbon-metal bond. This class does not include per se coordination compounds, which are substances having only donor bonds from heteroatoms, such as metal complexes of amines, halides, pseudohalides (CN, etc.), and the like. In practice organometallic compounds generally comprise, in addition to one or more carbon-metal bonds to an organic species, one or more donor bonds from a heteroatom. The carbon-metal bond to an organic species refers to a direct bond between a metal and a carbon atom of an organic group, such as phenyl, alkyl, alkenyl, etc., but does not refer to a metal bond to an “inorganic carbon,” such as the carbon of CN or CO.

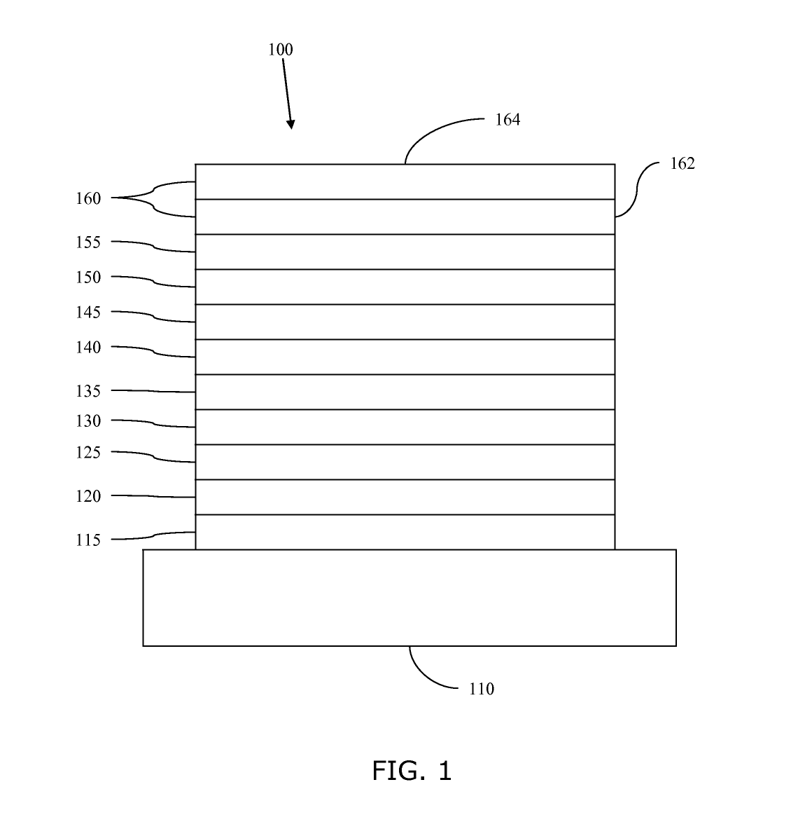

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, and a cathode 160. Cathode 160 is a compound cathode having a first conductive layer 162 and a second conductive layer 164. Device 100 may be fabricated by depositing the layers described, in order.

Substrate 110 may be any suitable substrate that provides desired structural properties. Substrate 110 may be flexible or rigid. Substrate 110 may be transparent, translucent or opaque. Plastic and glass are examples of preferred rigid substrate materials. Plastic and metal foils are examples of preferred flexible substrate materials. Substrate 110 may be a semiconductor material in order to facilitate the fabrication of circuitry. For example, substrate 110 may be a silicon wafer upon which circuits are fabricated, capable of controlling OLEDs subsequently deposited on the substrate. Other substrates may be used. The material and thickness of substrate 110 may be chosen to obtain desired structural and optical properties.

Anode 115 may be any suitable anode that is sufficiently conductive to transport holes to the organic layers. The material of anode 115 preferably has a work function higher than about 4 eV (a “high work function material”). Preferred anode materials include conductive metal oxides, such as indium tin oxide (ITO) and indium zinc oxide (IZO), aluminum zinc oxide (AlZnO), and metals. Anode 115 (and substrate 110) may be sufficiently transparent to create a bottom-emitting device. A preferred transparent substrate and anode combination is commercially available ITO (anode) deposited on glass or plastic (substrate). A flexible and transparent substrate-anode combination is disclosed in U.S. Pat. Nos. 5,844,363 and 6,602,540, which are incorporated by reference in their entireties. Anode 115 may be opaque and/or reflective. A reflective anode 115 may be preferred for some top-emitting devices, to increase the amount of light emitted from the top of the device. The material and thickness of anode 115 may be chosen to obtain desired conductive and optical properties. Where anode 115 is transparent, there may be a range of thickness for a particular material that is thick enough to provide the desired conductivity, yet thin enough to provide the desired degree of transparency. Other anode materials and structures may be used.

Hole transport layer 125 may include a material capable of transporting holes. Hole transport layer 130 may be intrinsic (undoped), or doped. Doping may be used to enhance conductivity. α-NPD and TPD are examples of intrinsic hole transport layers. An example of a p-doped hole transport layer is m-MTDATA doped with F₄-TCNQ at a molar ratio of 50:1, as disclosed in United States Patent Application Publication No. 2003/0230980 to Forrest et al., which is incorporated by reference in its entirety. Other hole transport layers may be used.

Emissive layer 135 may include an organic material capable of emitting light when a current is passed between anode 115 and cathode 160. Preferably, emissive layer 135 contains a phosphorescent emissive material, although fluorescent emissive materials may also be used. Phosphorescent materials are preferred because of the higher luminescent efficiencies associated with such materials. Emissive layer 135 may also comprise a host material capable of transporting electrons and/or holes, doped with an emissive material that may trap electrons, holes, and/or excitons, such that excitons relax from the emissive material via a photoemissive mechanism. Emissive layer 135 may comprise a single material that combines transport and emissive properties. Whether the emissive material is a dopant or a major constituent, emissive layer 135 may comprise other materials, such as dopants that tune the emission of the emissive material. Emissive layer 135 may include a plurality of emissive materials capable of, in combination, emitting a desired spectrum of light. Examples of phosphorescent emissive materials include Ir(ppy)₃. Examples of fluorescent emissive materials include DCM and DMQA. Examples of host materials include Alq₃, CBP and mCP. Examples of emissive and host materials are disclosed in U.S. Pat. No. 6,303,238 to Thompson et al., which is incorporated by reference in its entirety. Emissive material may be included in emissive layer 135 in a number of ways. For example, an emissive small molecule may be incorporated into a polymer. This may be accomplished by several ways: by doping the small molecule into the polymer either as a separate and distinct molecular species; or by incorporating the small molecule into the backbone of the polymer, so as to form a co-polymer; or by bonding the small molecule as a pendant group on the polymer. Other emissive layer materials and structures may be used. For example, a small molecule emissive material may be present as the core of a dendrimer.

Many useful emissive materials include one or more ligands bound to a metal center. A ligand may be referred to as “photoactive” if it contributes directly to the photoactive properties of an organometallic emissive material. A “photoactive” ligand may provide, in conjunction with a metal, the energy levels from which and to which an electron moves when a photon is emitted. Other ligands may be referred to as “ancillary.” Ancillary ligands may modify the photoactive properties of the molecule, for example by shifting the energy levels of a photoactive ligand, but ancillary ligands do not directly provide the energy levels involved in light emission. A ligand that is photoactive in one molecule may be ancillary in another. These definitions of photoactive and ancillary are intended as non-limiting theories.

Electron transport layer 145 may include a material capable of transporting electrons. Electron transport layer 145 may be intrinsic (undoped), or doped. Doping may be used to enhance conductivity. Alq₃ is an example of an intrinsic electron transport layer. An example of an n-doped electron transport layer is Bphen doped with Li at a molar ratio of 1:1, as disclosed in U.S. Patent Application Publication No. 2003/0230980 to Forrest et al., which is incorporated by reference in its entirety. Other electron transport layers may be used.

The charge carrying component of the electron transport layer may be selected such that electrons can be efficiently injected from the cathode into the LUMO (lowest unoccupied molecular orbital) energy level of the electron transport layer. The “charge carrying component” is the material responsible for the LUMO energy level that actually transports electrons. This component may be the base material, or it may be a dopant. The LUMO energy level of an organic material may be generally characterized by the electron affinity of that material and the relative electron injection efficiency of a cathode may be generally characterized in terms of the work function of the cathode material. This means that the preferred properties of an electron transport layer and the adjacent cathode may be specified in terms of the electron affinity of the charge carrying component of the ETL and the work function of the cathode material. In particular, so as to achieve high electron injection efficiency, the work function of the cathode material is preferably not greater than the electron affinity of the charge carrying component of the electron transport layer by more than about 0.75 eV, more preferably, by not more than about 0.5 eV. Similar considerations apply to any layer into which electrons are being injected.

Cathode 160 may be any suitable material or combination of materials known to the art, such that cathode 160 is capable of conducting electrons and injecting them into the organic layers of device 100. Cathode 160 may be transparent or opaque, and may be reflective. Metals and metal oxides are examples of suitable cathode materials. Cathode 160 may be a single layer, or may have a compound structure. FIG. 1 shows a compound cathode 160 having a thin metal layer 162 and a thicker conductive metal oxide layer 164. In a compound cathode, preferred materials for the thicker layer 164 include ITO, IZO, and other materials known to the art. U.S. Pat. Nos. 5,703,436; 5,707,745; 6,548,956; and 6,576,134, which are incorporated by reference in their entireties, disclose examples of cathodes including compound cathodes having a thin layer of metal such as Mg:Ag with an overlying transparent, electrically-conductive, sputter-deposited ITO layer. The part of cathode 160 that is in contact with the underlying organic layer, whether it is a single layer cathode 160, the thin metal layer 162 of a compound cathode, or some other part, is preferably made of a material having a work function lower than about 4 eV (a “low work function material”). Other cathode materials and structures may be used.

Blocking layers may be used to reduce the number of charge carriers (electrons or holes) and/or excitons that leave the emissive layer. An electron blocking layer 130 may be disposed between emissive layer 135 and the hole transport layer 125, to block electrons from leaving emissive layer 135 in the direction of hole transport layer 125. Similarly, a hole blocking layer 140 may be disposed between emissive layer 135 and electron transport layer 145, to block holes from leaving emissive layer 135 in the direction of electron transport layer 145. Blocking layers may also be used to block excitons from diffusing out of the emissive layer. The theory and use of blocking layers is described in more detail in U.S. Pat. No. 6,097,147 and United States Patent Application Publication No. 2003/0230980 to Forrest et al., which are incorporated by reference in their entireties.

As used herein, and as would be understood by one skilled in the art, the term “blocking layer” means that the layer provides a barrier that significantly inhibits transport of charge carriers and/or excitons through the device, without suggesting that the layer necessarily completely blocks the charge carriers and/or excitons. The presence of such a blocking layer in a device may result in substantially higher efficiencies as compared to a similar device lacking a blocking layer. Also, a blocking layer may be used to confine emission to a desired region of an OLED.

Generally, injection layers are comprised of a material that may improve the injection of charge carriers from one layer, such as an electrode or an organic layer, into an adjacent organic layer. Injection layers may also perform a charge transport function. In device 100, hole injection layer 120 may be any layer that improves the injection of holes from anode 115 into hole transport layer 125. CuPc is an example of a material that may be used as a hole injection layer from an ITO anode 115, and other anodes. In device 100, electron injection layer 150 may be any layer that improves the injection of electrons into electron transport layer 145. LiF/Al is an example of a material that may be used as an electron injection layer into an electron transport layer from an adjacent layer. Other materials or combinations of materials may be used for injection layers. Depending upon the configuration of a particular device, injection layers may be disposed at locations different than those shown in device 100. More examples of injection layers are provided in U.S. Pat. No. 7,071,615 to Lu et al., which is incorporated by reference in its entirety. A hole injection layer may comprise a solution deposited material, such as a spin-coated polymer, e.g., PEDOT:PSS, or it may be a vapor deposited small molecule material, e.g., CuPc or MTDATA.

A hole injection layer (HIL) may planarize or wet the anode surface so as to provide efficient hole injection from the anode into the hole injecting material. A hole injection layer may also have a charge carrying component having HOMO (highest occupied molecular orbital) energy levels that favorably match up, as defined by their herein-described relative ionization potential (IP) energies, with the adjacent anode layer on one side of the HIL and the hole transporting layer on the opposite side of the HIL. The “charge carrying component” is the material responsible for the HOMO energy level that actually transports holes. This component may be the base material of the HIL, or it may be a dopant. Using a doped HIL allows the dopant to be selected for its electrical properties, and the host to be selected for morphological properties such as wetting, flexibility, toughness, etc. Preferred properties for the HIL material are such that holes can be efficiently injected from the anode into the HIL material. In particular, the charge carrying component of the HIL preferably has an IP not more than about 0.7 eV greater that the IP of the anode material. More preferably, the charge carrying component has an IP not more than about 0.5 eV greater than the anode material. Similar considerations apply to any layer into which holes are being injected. HIL materials are further distinguished from conventional hole transporting materials that are typically used in the hole transporting layer of an OLED in that such HIL materials may have a hole conductivity that is substantially less than the hole conductivity of conventional hole transporting materials. The thickness of the HIL of the present invention may be thick enough to help planarize or wet the surface of the anode layer. For example, an HIL thickness of as little as 10 nm may be acceptable for a very smooth anode surface. However, since anode surfaces tend to be very rough, a thickness for the HIL of up to 50 nm may be desired in some cases. Examples of hole injecting materials that can be used are shown in Table 1 below.

TABLE 1

| | | Relevant Publication |
|---|---|---|
| | | (including patent |
| Class of Materials | Examples | publications) |
| Phthalocyanine and porphryin compounds | 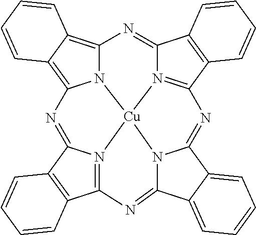 | Appl. Phys. Lett. 69, 2160 (1996) |
| Starburst triarylamines | 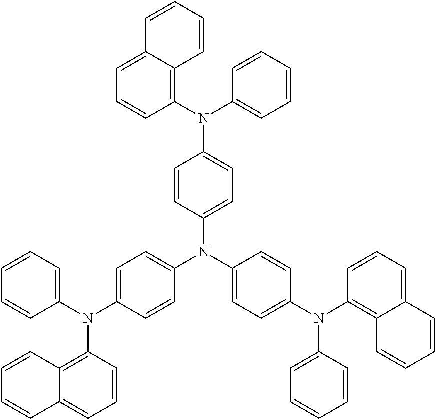 | J. Lumin. 72-74, 985 (1997) |
| CFₓ Fluorohydrocarbon polymer | 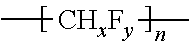 | Appl. Phys. Lett. 78, 673 (2001) |
| Conducting polymers (e.g., PEDOT:PSS, polyaniline, polypthiophene) | 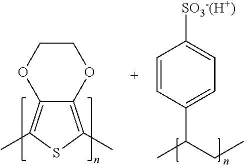 | Synth. Met. 87, 171 (1997); WO 2007/002683 |
| | 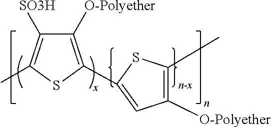 | Society of Information Display Digest, 32.1 (2010) p. 461; Available from Plextronics Inc, Pittsburgh, PA |
| Phosphonic acid and sliane SAMs | 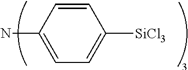 | US 2003/0162053 |
| Triarylamine or polythiophene polymers with conductivity dopants | 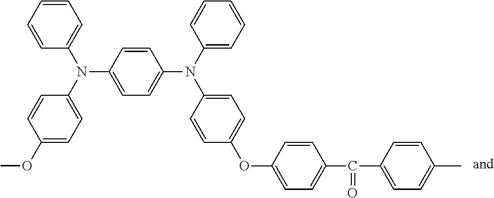 | EP 01725079 |
| | 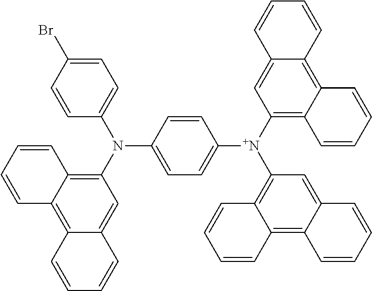 | |
| | 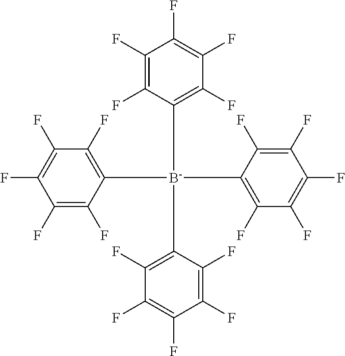 | |
| Arylamines complexed with metal oxides such as molybdenum and tungsten oxides | 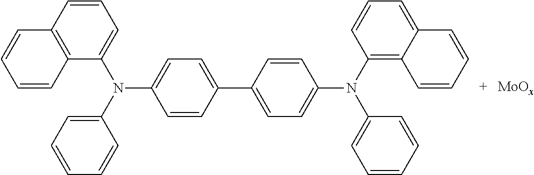 | SID Symposium Digest, 37, 923 (2006); WO 2009/018009 |
| p-type semiconducting organic complexes | 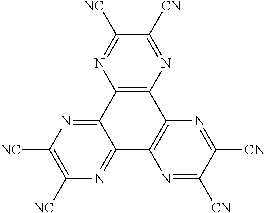 | US 2002/0158242 |
| Metal organometallic complexes | 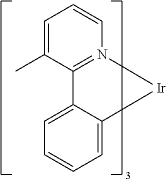 | US 2006/0240279 |
| Cross-linkable compounds | 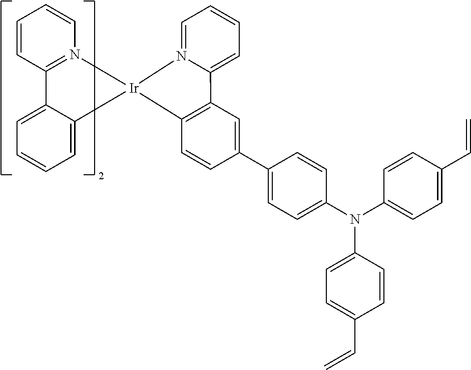 | US 2008/0220265 |
| Oligoaniline compounds | 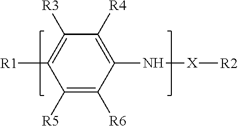 | WO 2008/032617 Available from Nissan Chemical Ind., Ltd |

A protective layer may be used to protect underlying layers during subsequent fabrication processes. For example, the processes used to fabricate metal or metal oxide top electrodes may damage organic layers, and a protective layer may be used to reduce or eliminate such damage. In device 100, protective layer 155 may reduce damage to underlying organic layers during the fabrication of cathode 160. Preferably, a protective layer has a high carrier mobility for the type of carrier that it transports (electrons in device 100), such that it does not significantly increase the operating voltage of device 100. CuPc, BCP, and various metal phthalocyanines are examples of materials that may be used in protective layers. Other materials or combinations of materials may be used. The thickness of protective layer 155 is preferably thick enough that there is little or no damage to underlying layers due to fabrication processes that occur after organic protective layer 160 is deposited, yet not so thick as to significantly increase the operating voltage of device 100. Protective layer 155 may be doped to increase its conductivity. For example, a CuPc or BCP protective layer 160 may be doped with Li. A more detailed description of protective layers may be found in U.S. Pat. No. 7,071,615 to Lu et al., which is incorporated by reference in its entirety.

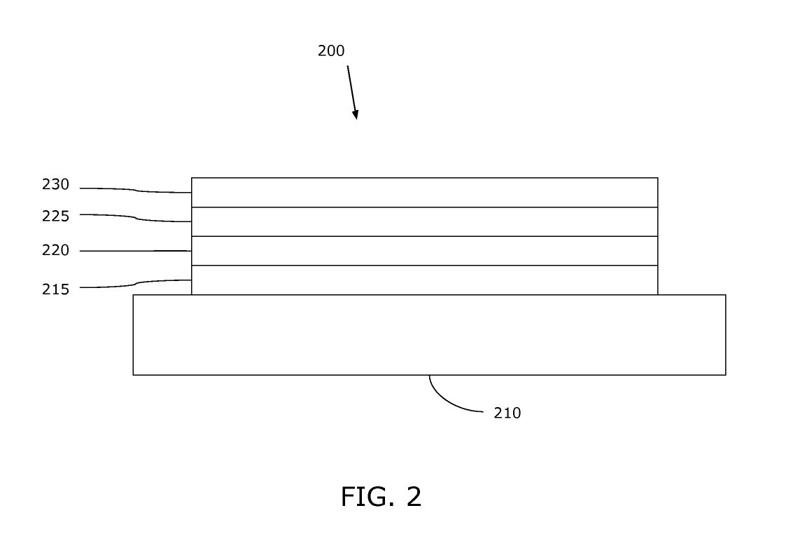

FIG. 2 shows an inverted OLED 200. The device includes a substrate 210, an cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968 to Shtein et al., which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink jet and OVJP. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

The molecules disclosed herein may be substituted in a number of different ways without departing from the scope of the invention. For example, substituents may be added to a compound having three bidentate ligands, such that after the substituents are added, one or more of the bidentate ligands are linked together to form, for example, a tetradentate or hexadentate ligand. Other such linkages may be formed. It is believed that this type of linking may increase stability relative to a similar compound without linking, due to what is generally understood in the art as a “chelating effect.”

Devices fabricated in accordance with embodiments of the invention may be incorporated into a wide variety of consumer products, including flat panel displays, computer monitors, televisions, billboards, lights for interior or exterior illumination and/or signaling, heads up displays, fully transparent displays, flexible displays, laser printers, telephones, cell phones, personal digital assistants (PDAs), laptop computers, digital cameras, camcorders, viewfinders, micro-displays, vehicles, a large area wall, theater or stadium screen, or a sign. Various control mechanisms may be used to control devices fabricated in accordance with the present invention, including passive matrix and active matrix. Many of the devices are intended for use in a temperature range comfortable to humans, such as 18-30° C., and more preferably at room temperature (20-25° C.).

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In one aspect, the present invention provides an organic electronic device comprising an organic charge transport layer. The charge transport layer comprises a covalently cross-linked host matrix. The covalently cross-linked host matrix comprises a charge transport compound as molecular subunits that are cross-linked to each other, i.e., the cross-linked matrix is formed by the cross-linking of the charge transport compound. Being formed of a charge transport compound as molecular subunits, the cross-linked host matrix of the present invention is capable of transporting charges (holes, electrons, or both). In other words, if the cross-linked host matrix of the present invention were to be used as the sole material for a charge transport layer (e.g., hole transport layer or electron transport layer) in an OLED, the cross-linked host matrix would conduct charge through the device and the device would be operative. This is in contrast to cross-linked matrixes that are inert to charge transfer reactions (such as the inert cross-linked polymer network described in Zhou et al., Applied Physics Letters 96:013504, 2010). If an inert cross-linked matrix were to be used as the sole material for a charge transport layer in an OLED, the inert cross-linked host matrix would not conduct charge and the device would be inoperative.

The charge transport layer further comprises a second charge transport compound as an additive. The additive charge transport compound is a separate and distinct molecular species from the host matrix. The host matrix and the additive combine in such a manner to form a single charge transport layer (but this does not limit the device to having a single charge transport layer). The additive may combine with the host matrix in any suitable way to form a single charge transport layer. For example, the additive charge transport compound may be uniformly or homogenously dispersed in the cross-linked host matrix, or the additive charge transport compound may be embedded in the cross-linked host matrix, or the additive charge transport compound may be dispersed in the cross-linked host matrix in discrete aggregates (e.g., as nanoparticles).

As used herein, the term “charge transport compound” means a compound that can both accept a charge carrier and transport the charge carrier through the charge transport layer with relatively high efficiency and small loss of charge. The term “charge transport compound” is further intended to exclude compounds that act only as charge acceptors in the charge transport layer but cannot efficiently transport them.

The charge transport compound may be hole transporting or electron transporting. As used herein, the term “hole transport compound” means a compound that is capable of both accepting a positive charge carrier (i.e., a hole) and efficiently transporting it through the charge transport layer. As explained above, the term “hole transport compound” is further intended to exclude compounds that merely act as hole acceptors but cannot efficiently transport them. As used herein, the term “electron transport compound” means a charge transport compound that is capable of accepting an electron and efficiently transporting it through the charge transport layer. As explained above, the term “electron transport compound” is further intended to exclude compounds that merely act as electron acceptors in the charge transport layer but cannot efficiently transport them when used alone in the charge transport layer.

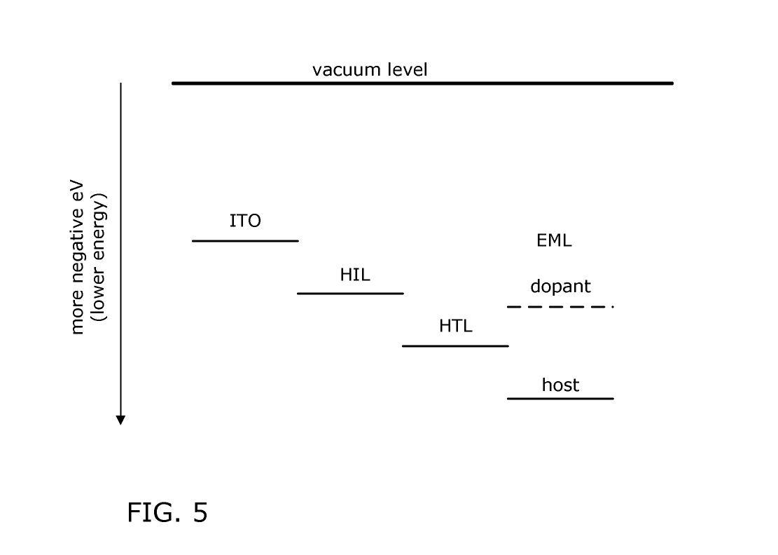

Compounds that are useful as charge transport compounds can be characterized by their LUMO/HOMO energy levels. In certain embodiments, a hole transport compound used in the present invention has a HOMO energy level that is between the work function of indium tin oxide (ITO), which is a commonly used anode material (ITO is being used as a reference standard here, but the device is not limited to having an ITO anode), and the HOMO energy level of the host material in the emissive layer. For example, the hole transport compound may have a HOMO energy level that is more negative (lower energy) than the work function of indium tin oxide (ITO) and less negative (higher energy) than the HOMO energy level of the host material in the emissive layer. An example of how the HOMO energy level of a hole transport layer may be aligned relative to other layers in an organic light-emitting device is shown in FIG. 5. In FIG. 5, the HOMO energy level of the hole transport layer (HTL) is between the ITO anode and the host material in the emissive layer (EML). HIL is the hole injection layer. In some cases, the hole transport compound has a HOMO energy level that is at least 0.1 eV more negative (lower energy) than the work function of indium tin oxide (ITO) and at least 0.1 eV less negative (higher energy) than the HOMO energy level of the host material in the emissive layer.

The additive hole transport compound improves hole mobility in the hole transport layer. In some cases, the additive hole transport compound has a higher hole mobility than the host matrix and/or the host hole transport compound used to make the host matrix. Hole conductivity σ=p*e*μ, where “p” is the hole density (number of free holes per unit volume to be transported by the electric field), “e”=1.6×10⁻¹⁹ Coulomb (charge), and μ is the hole mobility. Thus, a hole transport layer may be doped with an electron acceptor, such as F₄-TCNQ, to increase the hole density in the hole transport layer and thereby increase conductivity. However, a hole transport compound used as an additive in the present invention may improve conductivity in the hole transport layer by increasing hole mobility rather than by increasing hole density.

Any suitable charge transport compound may be used in the charge transport layer for the host matrix or the additive. Examples of hole transport compounds that can be used in the present invention include arylamine compounds such as α-NPD and TPD, and carbazole derivatives such as CBP and mCP, as shown below.

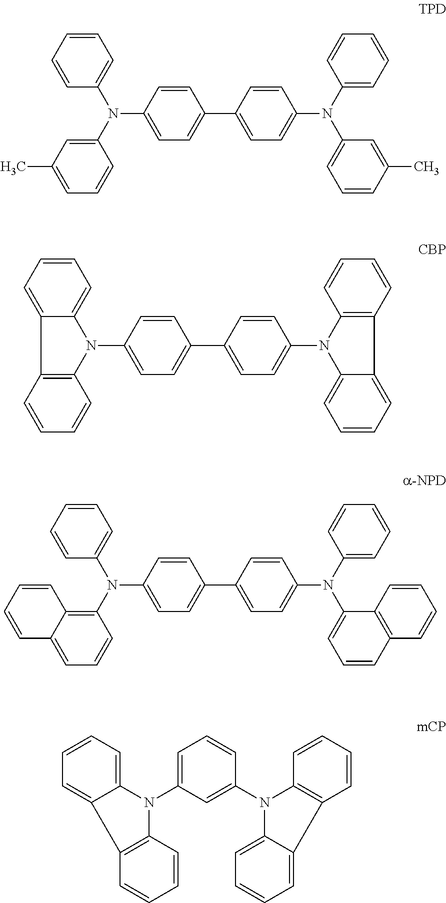

Other examples of hole transport compounds suitable for use in the present invention include those shown in Table 2 below.

TABLE 2

| | | Relevant Publication |
|---|---|---|
| | | (including patent |
| Class of Materials | Example | publications) |
| Starburst triarylamines | 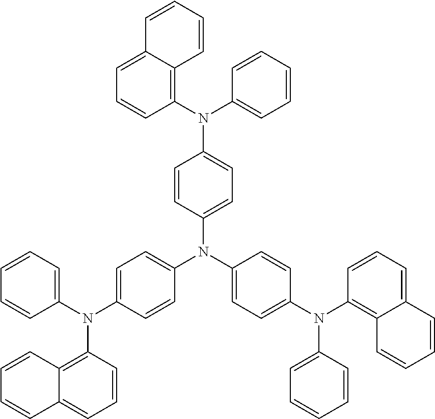 | J. Lumin. 72-74, 985 (1997) |
| CFₓ Fluorohydrocarbon polymer | 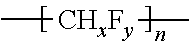 | Appl. Phys. Lett. 78, 673 (2001) |
| Triarylamine or polythiophene polymers with conductivity dopants | 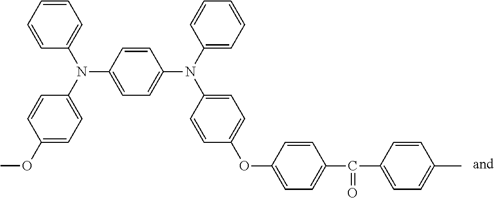 | EP 01725079 |
| | 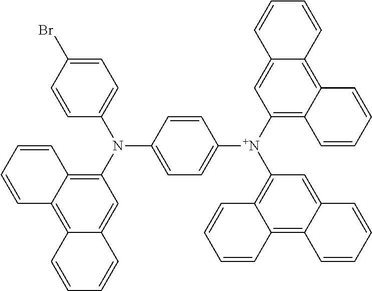 | |
| | 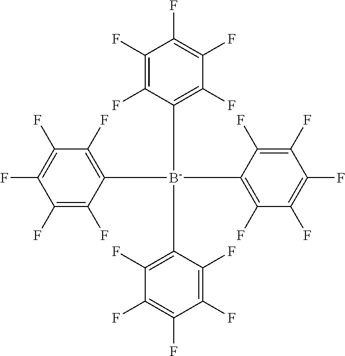 | |
| Arylamines complexed with metal oxides such as molybdenum and tungsten oxides | 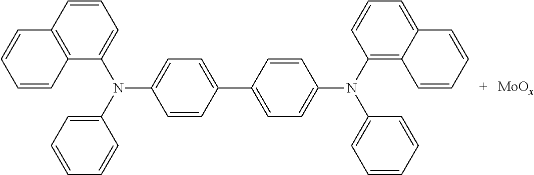 | SID Symposium Digest, 37, 923 (2006); WO 2009/018009 |
| p-type semiconducting organic complexes | 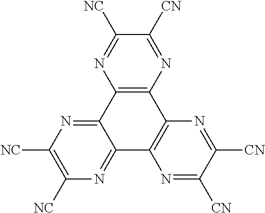 | US 2002/0158242 |
| Triarylamines (e.g., TPD, α-NPD) | 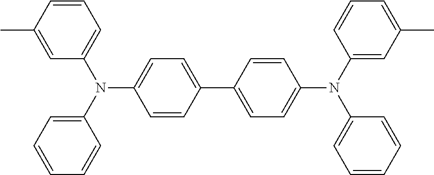 | Appl. Phys. Lett. 51, 913 (1987) |
| | 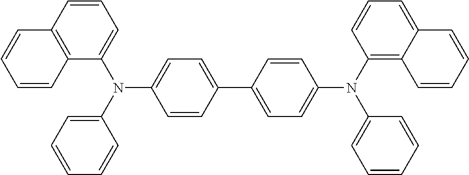 | U.S. Pat. No. 5,061,569 |
| | 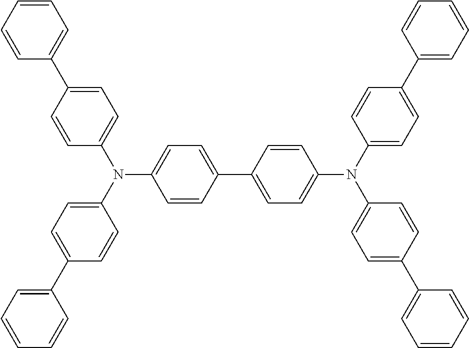 | EP 0650955 |
| | 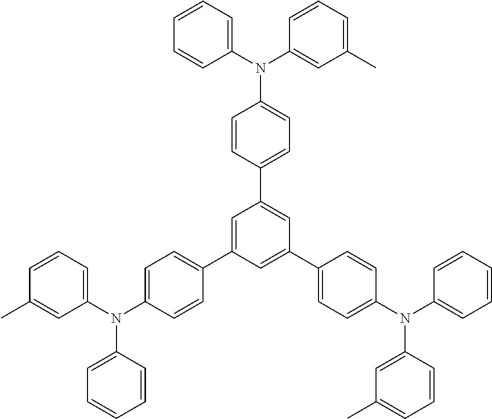 | J. Mater. Chem. 3, 319 (1993) |
| | 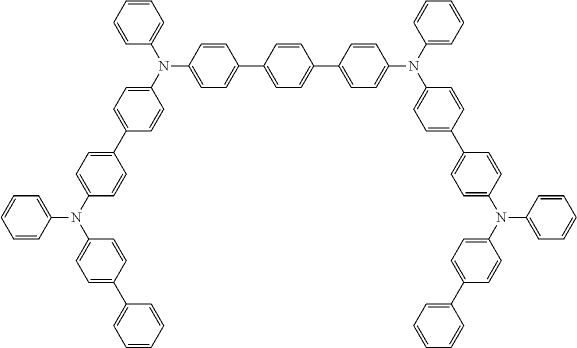 | Appl. Phys. Lett. 90, 183503 (2007) |
| | 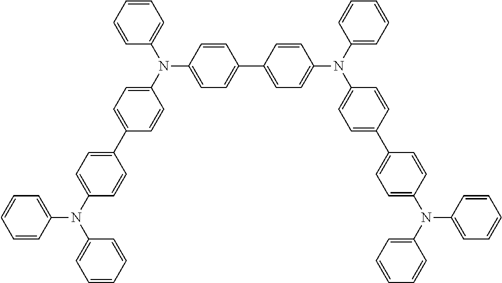 | Appl. Phys. Lett. 90, 183503 (2007) |
| Triaylamine on spirofluorene core | 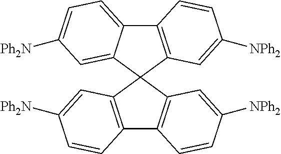 | Synth. Met. 91, 209 (1997) |
| Arylamine carbazole compounds | 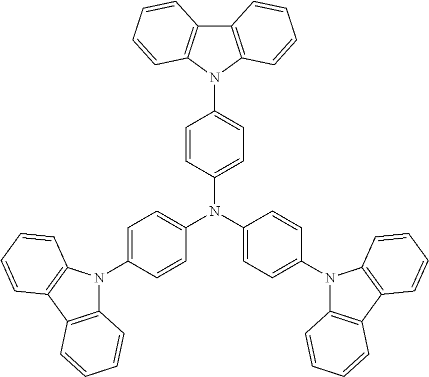 | Adv. Mater. 6, 677 (1994); US 2008/0124572 |
| Triarylamine with (di)benzothiophene/ (di)benzofuran | 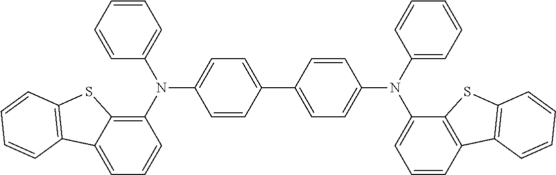 | US 2007/0278938; US 2008/0106190 |
| Indolocarbazoles | 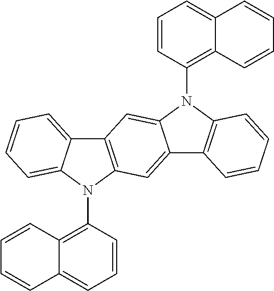 | Synth. Met. 111, 421 (2000) |
| Isoindole compounds | 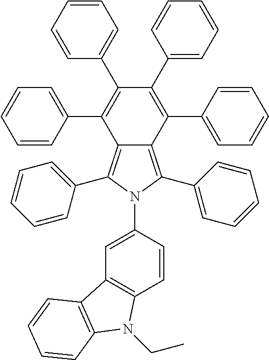 | Chem. Mater. 15, 3148 (2003) |
| Metal carbene complexes | 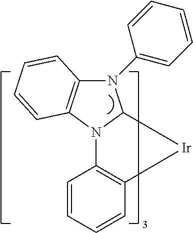 | US 2008/0018221 |

The charge transport compound used to make the host matrix has or is modified to have one or more reactive groups which are able to form covalent bond cross-links with another reactive group. As used herein, “reactive group” refers to any atom, functional group, or portion of a molecule having sufficient reactivity to form at least one covalent bond with another reactive group in a chemical reaction. The cross-linking may be between two identical or two different reactive groups. Various reactive groups are known in the art, including those derived from amines, imides, amides, alcohols, esters, epoxides, siloxanes, vinyl, and strained ring compounds. Examples of such reactive groups include oxetane, styrene, and acrylate functional groups. Charge transport compounds having such cross-linkable reactive groups are described in Nuyken et al., Designed Monomers and Polymers 5(2/3):195-210 (2002); Bacher et al., Macromolecules 32:4551-57 (1999); Bellmann et al., Chem. Mater. 10:1668-76 (1998); Domercq et al., Chem. Mater. 15:1491-96 (2003); Muller et al., Synthetic Metals 111/112:31-34 (2000); Bacher et al., Macromolecules 38:1640-47 (2005); and Domercq et al., J. Polymer Sci. 41:2726-32 (2003), U.S. Patent Publication Nos. 2004/0175638 (Tierney et al.) and 2005/0158523 (Gupta et al.); and U.S. Pat. Nos. 5,929,194 (Woo et al.) and 6,913,710 (Farrand et al.), which are all incorporated by reference herein. Non-limiting examples of charge transport compounds suitable for use in making the host matrix include cross-linkable derivatives of arylamines, such as cross-linkable forms of TPD or α-NPD. In certain instances, styryl group-bearing arylamine derivatives, such as N⁴,N⁴′-di(naphthalen-1-yl)-N⁴,N⁴′-bis(4-vinylphenyl)biphenyl-4,4′-diamine (referred to as HTL-1 below), can be used as hole transport compounds for the host matrix because of their moderate cross-linking temperatures.

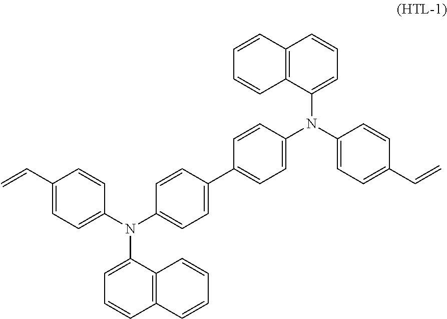

In some embodiments, the charge transport layer of the present invention is an electron transport layer. In such embodiments, the cross-linked host matrix can be made from any suitable electron transport compound having one or more reactive groups that can form cross-linking bonds. Examples of such cross-linkable electron transport compounds include the following:

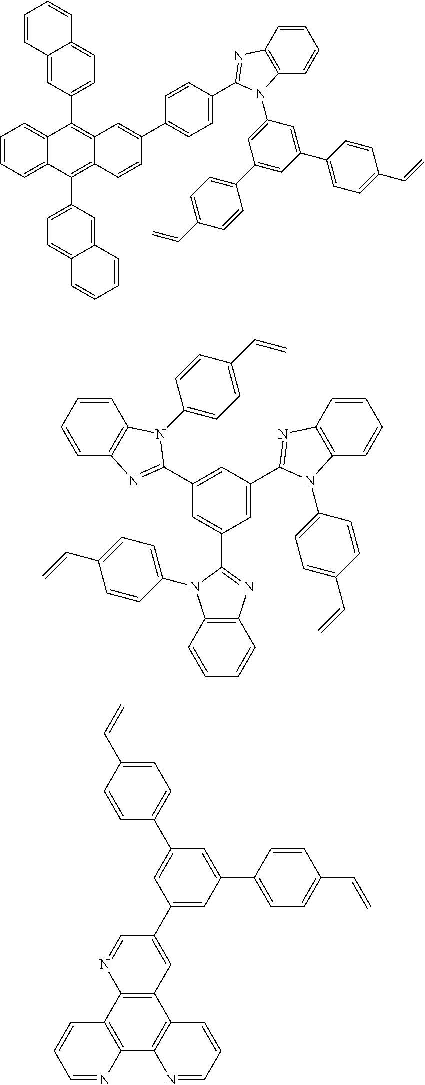

Any suitable electron transporting additive compound (small molecule or polymer) can be used in the cross-linked electron transport layer. Examples of electron transporting additive compounds that can be used include those having one or more of the following building blocks:

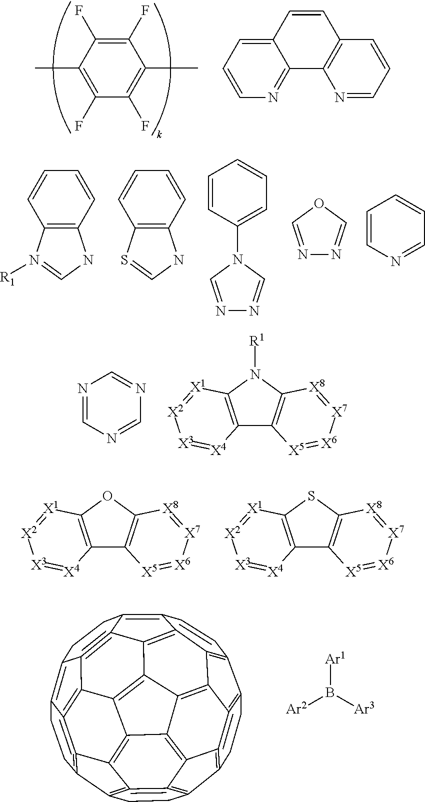

In the above compounds, R¹ is hydrogen, alkyl, alkoxy, amino, alkenyl, alkynyl, arylalkyl, heteroalkyl, aryl, or heteroaryl. Ar¹, Ar², and Ar³ are aryls or heteroaryls. “k” is an integer from 0 to 20. X¹ to X⁸ are C (including CH) or N. Other examples of electron transporting additive compounds that can be used in the present invention include those having 2-phenylbenzimidazole moieties and those shown in Table 3 below:

TABLE 3
Electron transporting compounds

| | | |
|---|---|---|
| Anthracene- benzoimidazole compounds | 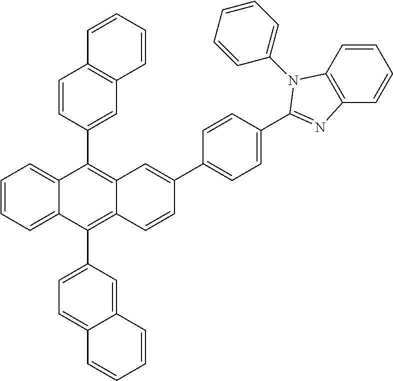 | W02003060956 |
| | 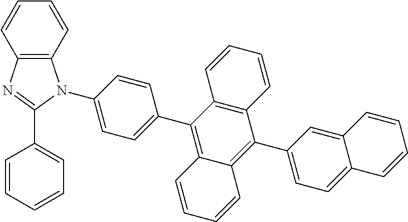 | US20090179554 |
| Aza triphenylene derivatives | 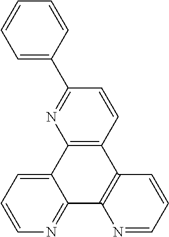 | US20090115316 |
| Anthracene-benzothiazole compounds | 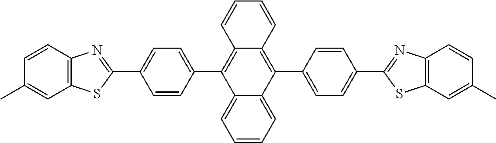 | Appl. Phys. Lett. 89, 063504 (2006) |
| Metal 8- hydroxyquinolates (e.g., Alq₃, Zrq₄) | 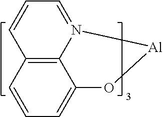 | Appl. Phys. Lett. 51, 913 (1987) U.S. Pat. No. 7,230,107 |
| Metal hydroxybenoquinolates | 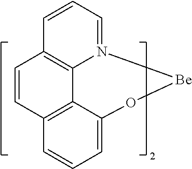 | Chem. Lett. 5, 905 (1993) |
| Bathocuprine compounds such as BCP, BPhen, etc | 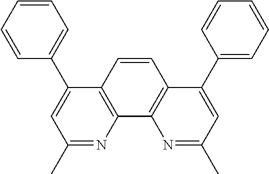 | Appl. Phys. Lett. 91, 263503 (2007) |
| | 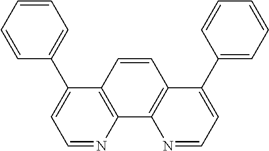 | Appl. Phys. Lett. 79, 449 (2001) |
| 5-member ring electron deficient heterocycles (e.g., triazole, oxadiazole, imidazole, benzoimidazole) | 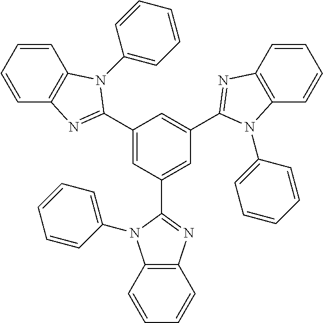 | Appl. Phys. Lett. 74, 865 (1999) |
| | 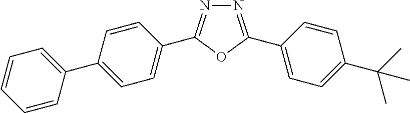 | Appl. Phys. Lett. 55, 1489 (1989) |
| | 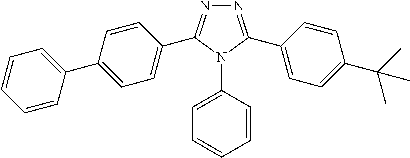 | Jpn. J. Apply. Phys. 32, L917 (1993) |
| Silole compounds | 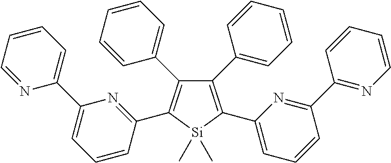 | Org. Electron. 4, 113 (2003) |
| Arylborane compounds | 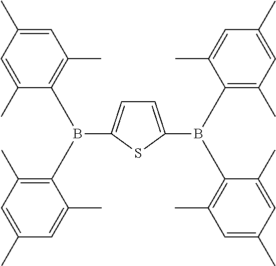 | J. Am. Chem. Soc. 120, 9714 (1998) |
| Fluorinated aromatic compounds | 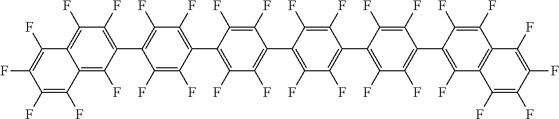 | J. Am. Chem. Soc. 122, 1832 (2000) |
| Fullerene (e.g., C60) | 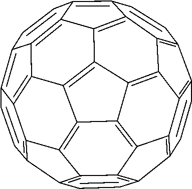 | US20090101870 |
| Triazine complexes | 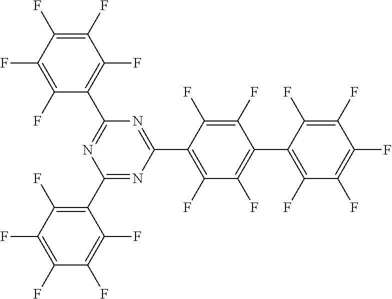 | US20040036077 |
| Zn (N\hat{ }N)complexes | 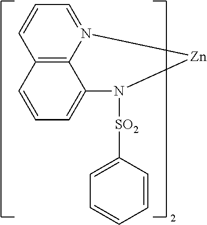 | U.S. Pat. No. 6,528,187 |

Cross-linking can be performed by exposing the cross-linkable charge transport compound to heat and/or actinic radiation, including UV light, gamma rays, or x-rays. Cross-linking may be carried out in the presence of an initiator that decomposes under heat or irradiation to produce free radicals or ions that initiate the cross-linking reaction. The cross-linking may be performed in-situ during fabrication of the device.

Cross-linked organic layers have been found to be solvent resistant (see, for example, U.S. Pat. No. 6,982,179 to Kwong et al.), which is incorporated by reference herein. An organic layer formed of a covalently cross-linked matrix can be useful in the fabrication of organic electronic devices by solution processing techniques, such as spin coating, spray coating, dip coating, ink jet, and the like. In solution processing, the organic layers are deposited in a solvent. Therefore, in a multi-layered structure, any underlying layer is preferably resistant to the solvent that is being deposited upon it.

Thus, in certain embodiments, the cross-linking of the charge transport compound for the host matrix can render the organic layer resistant to solvents. As such, the organic layer can avoid being dissolved, morphologically influenced, or degraded by a solvent that is deposited over it. The organic layer may be resistant to a variety of solvents used in the fabrication of organic electronic devices, including toluene, xylene, anisole, and other substituted aromatic and aliphatic solvents. The process of solution deposition and cross-linking can be repeated to create a multilayered structure.

As explained above, the charge transport layer further comprises an organic charge transport compound as an additive (i.e., a second charge transport compound that transports the same type of charge as the first charge transport compound or the covalently cross-linked host matrix). In some cases, the additive charge transport compound is a small molecule compound. For example, the additive charge transport compound may have a molecular weight of less than 2,000, and in some cases, less than 800. In some cases, the additive charge transport compound is not cross-linkable (it does not have any cross-linkable reactive groups). In some cases, the additive charge transport compound has a relatively low solubility in an organic solvent. For example, the additive charge transport compound may have a solubility of less than 1 wt % in toluene (toluene is being used as a reference standard here, but the present invention is not limited to using toluene). Thus, the present invention allows for charge transport compounds that have low solubility in an organic solvent to nevertheless be deposited by solution processing techniques. By combining the low solubility (additive) charge transport compound with cross-linking of the host charge transport compound, solution deposition of the additive charge transport compound may become feasible.

In some cases, the additive charge transport compound has the same molecular structure as the host charge transport compound used to form the cross-linked host matrix except that the host charge transport compound has one or more cross-linking reactive groups on the molecule that are not present on the additive charge transport compound. For example, α-NPD and the cross-linkable HTL-1 have the same molecular structure except for the presence of cross-linkable styryl groups on HTL-1.

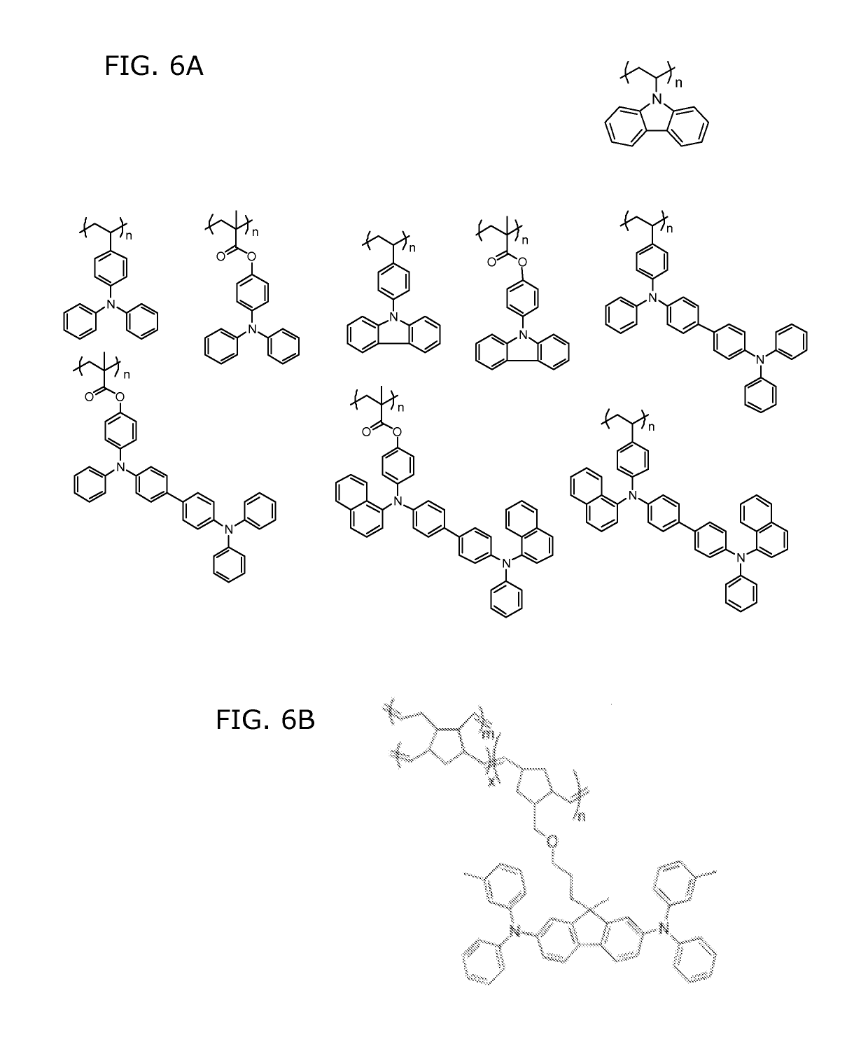

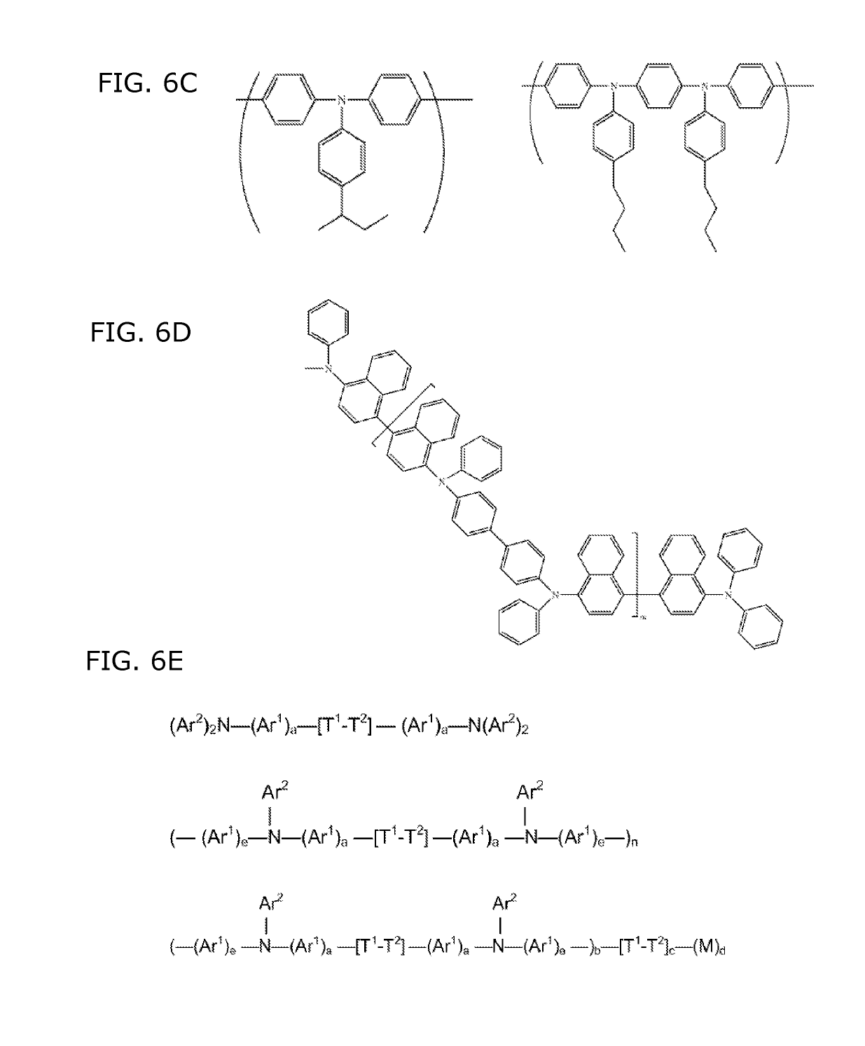

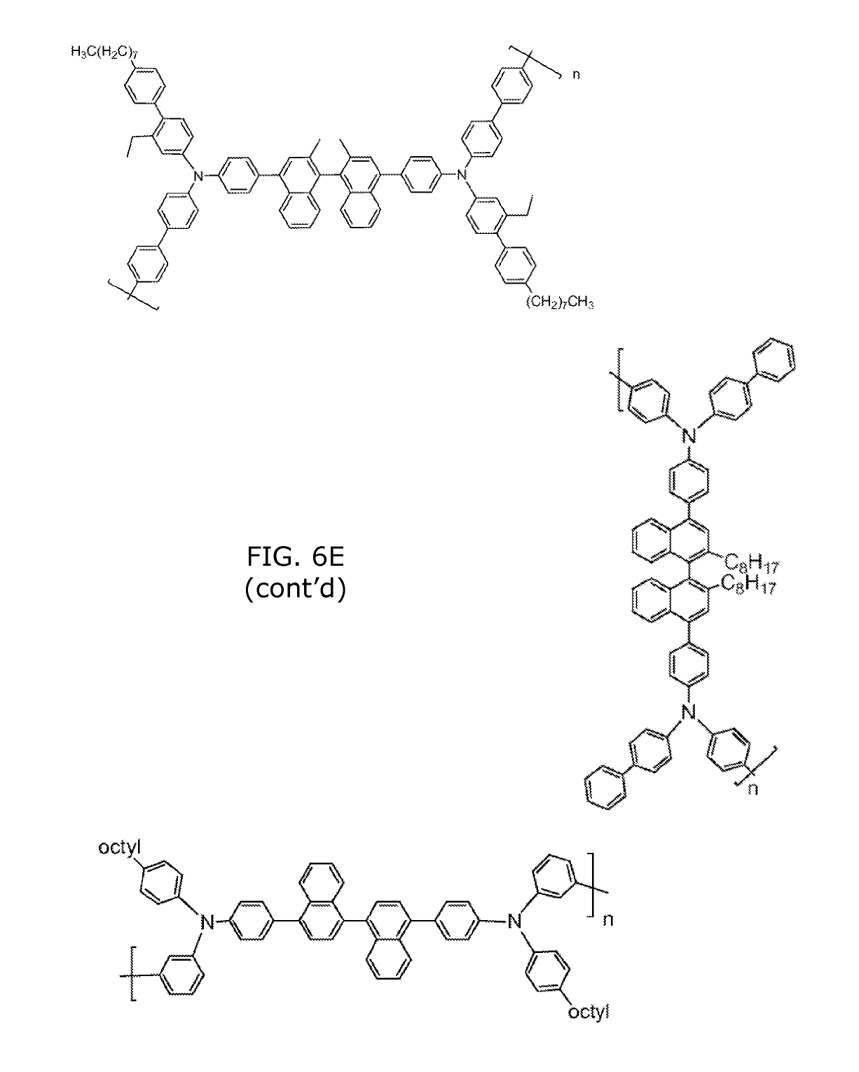

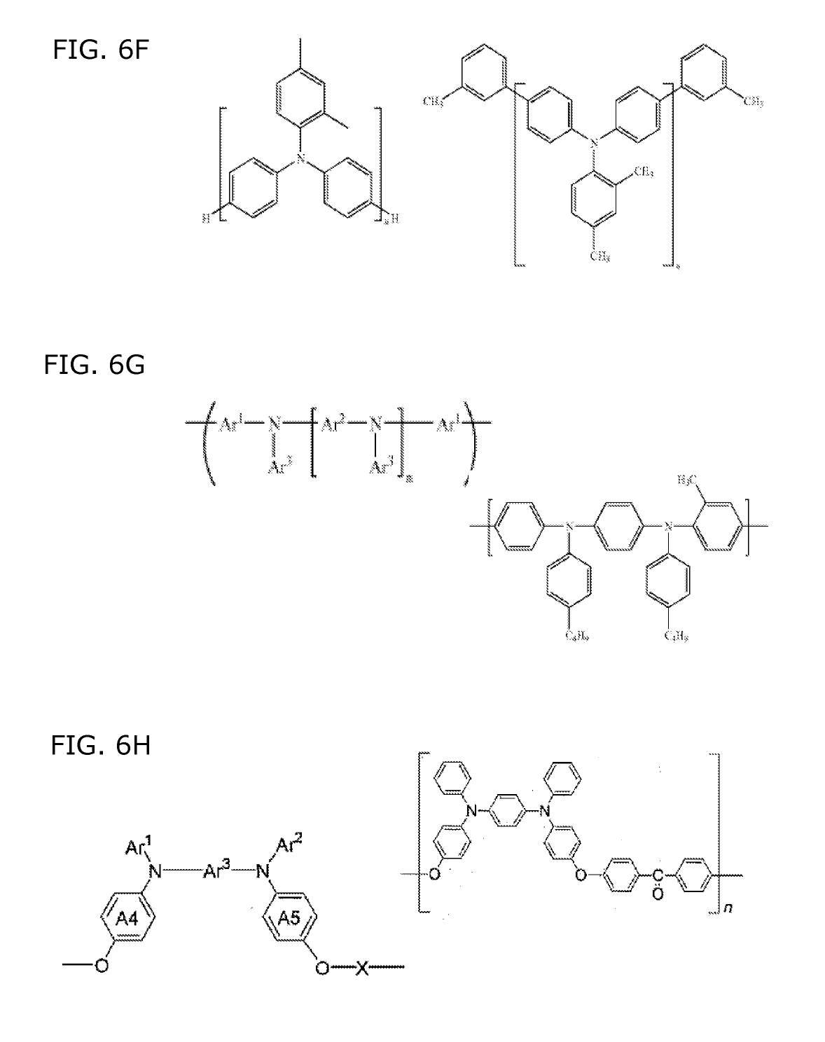

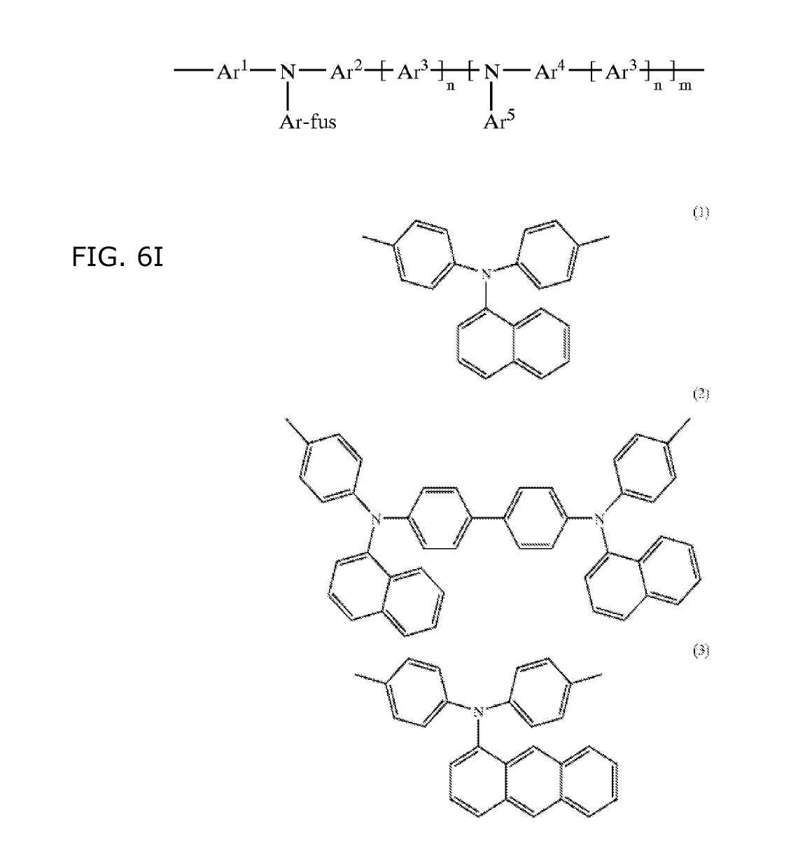

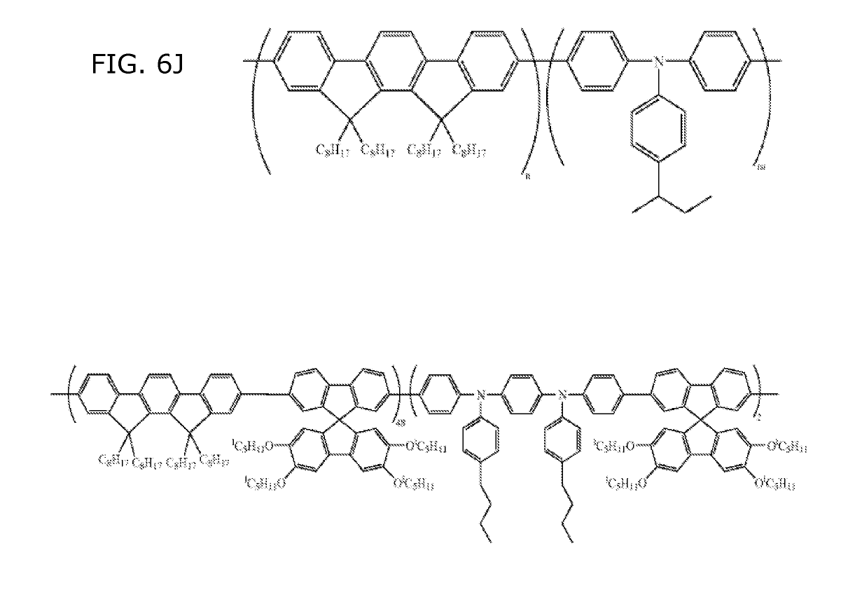

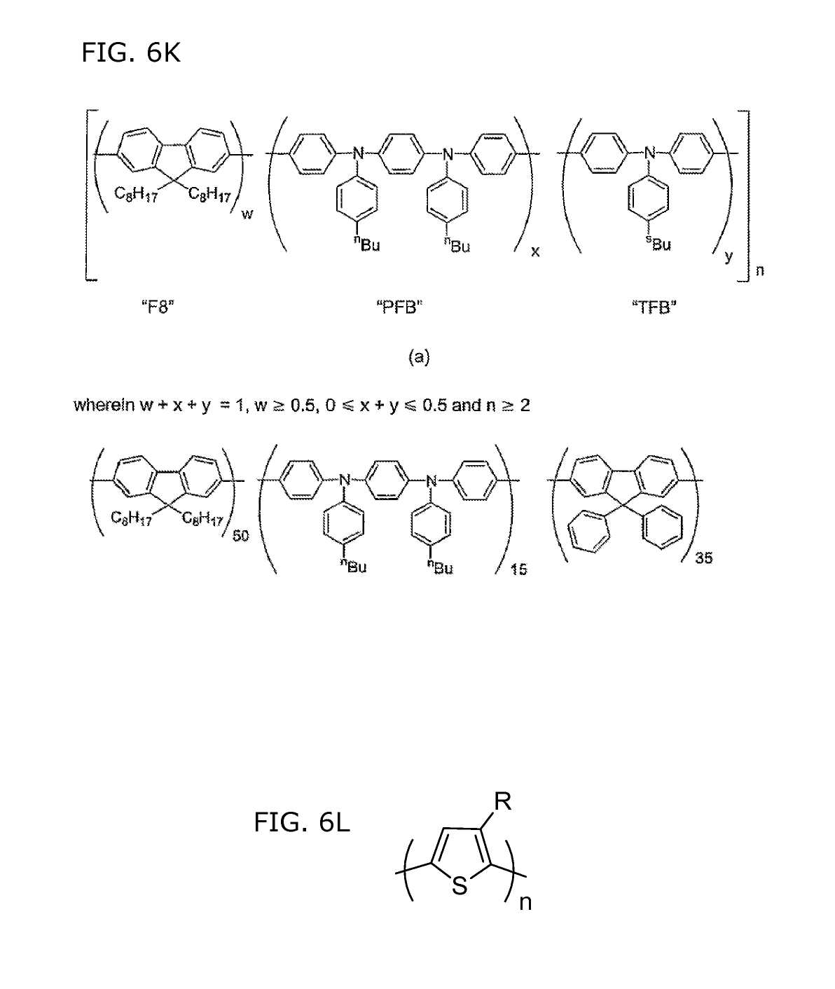

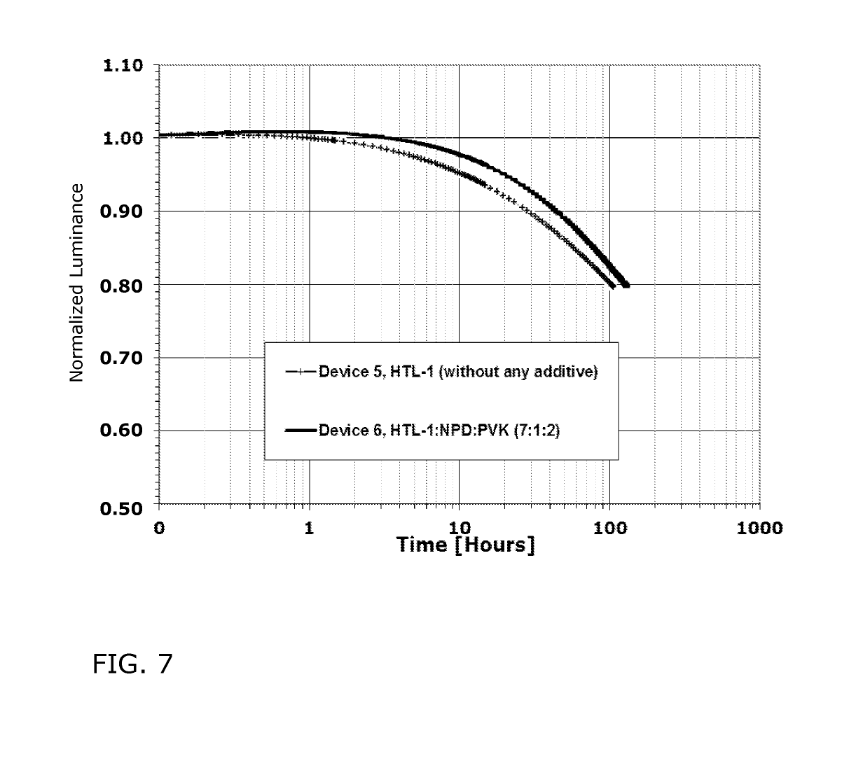

In some cases, the additive charge transport compound is a polymer compound. A variety of polymer compounds having charge transporting capabilities (i.e., hole transporting, electron transporting, or both) may be suitable for use as the additive compound. In some embodiments, the additive polymer compound may include carbazole and/or triarylamine moieties, such as those shown in FIGS. 6A and 6B (see Tetrahedron 60 (2004) pp. 7169-7176: “Synthesis of acrylate and norbornene polymers with pendant 2,7-bis(diarylamino)fluorene hole-transport groups”). In some embodiments, the additive polymer compound may be selected from those shown in FIG. 6C (see WO 99/48160 and WO 03/00773); or FIG. 6D (see US 2008/0303427); or FIG. 6E (see WO 09/67419), where Ar¹ is phenylene, substituted phenylene, naphthylene, or substituted naphthylene; Ar² is an aryl group; M is a conjugated moiety; T¹ and T² are independently conjugated moieties that are connected in a non-planar configuration; a is an integer from 1 to 6; b, c, and d are mole fractions such that b+c+d=1.0, with the proviso that c is not zero, and at least one of b and d is not zero, and when b is zero, M comprises at least two tharylamine units; e is an integer from 1 to 6; and n is an integer greater than 1.

In some embodiments, the additive polymer compound may be selected from those shown in FIG. 6F (see US 2006/0210827); or FIG. 6G (see US 2008/0217605), where each Ar¹ and each Ar² is arylene, and each Ar³ is an optionally substituted phenyl, such as a nitrogen-containing heteroaryl or a sulfur-containing heteroaryl, preferably optionally substituted 2-thienyl; or FIG. 6H (see JP 2005-75948). In some embodiments, the additive polymer compound may be a polyfluorene-triarylamine copolymer, such as those shown in FIG. 6I (see US 2006/0058494), where Ar¹ and Ar³ are each an aromatic or heteroaromatic ring system which has from 2 to 40 carbon atoms; Ar² and Ar⁴ are each Ar¹, Ar³, or a stilbenzylene or tolanylene unit; Ar-fus is an aromatic or heteroaromatic ring system which has at least 9 but at most 40 atoms (carbon or heteroatoms) in the conjugated system and which consists of at least two fused rings; Ar⁵ is an aromatic or heteroaromatic ring system which has from 2 to 40 carbon atoms; m and n are each 0, 1 or 2. In some embodiments, the additive polymer compound may be selected from those shown in FIG. 6J (see US 2006/0149016); or FIG. 6K (see WO 03/095586); or polythiophene derivatives, such as that shown in FIG. 6L.

Any suitable amount of the additive charge transport compound may be used in the charge transport layer. Preferably, the additive charge transport compound is present in an amount ranging from 1 to 40 wt % relative to the cross-linked host matrix, and more preferably from 5 to 30 wt %. In cases where an organic solution is used to deposit the charge transport layer, the organic solution may contain the additive charge transport compound in an amount ranging from 1 to 40 wt % relative to the host charge transport compound, and more preferably from 5 to 30 wt %. The concentration of the additive charge transport compound in the organic solution may be less than 1 wt %.

In embodiments where the charge transport layer of the present invention is a hole transport layer located directly adjacent the emissive layer and the emissive layer comprises a host material and a phosphorescent dopant material, in some cases, the hole transport layer also serves as an electron blocking layer. The composition of this hole transport layer can be selected so that it has an electron blocking function. In some cases, the additive compound in this hole transport layer has a LUMO that is less electronegative (higher energy) than both the LUMO of the host compound and the LUMO of the phosphorescent dopant compound in the emissive layer. In some cases, the LUMO of the additive compound is at least 0.1 eV or 0.2 eV less electronegative than both the LUMO of the host compound and the LUMO of the phosphorescent dopant compound in the emissive layer. In some cases, the additive compound has a wide HOMO-LUMO band gap. For example, the HOMO-LUMO band gap of the additive compound may be at least 2.4 eV. This energy level configuration may provide an energy barrier against the flow of electrons into the hole transport layer. This electron blocking function serves to confine electrons in the emissive layer, which can further prolong device lifetimes because electron migration into the hole transport layer can reduce device lifetime and disrupt the hole transport function in the hole transport layer.

In some embodiments, the devices of the present invention have a hole injection layer between the emissive layer and the anode. The hole injection layer may be made using any suitable hole injection material. In some cases, the hole injection layer comprises a small molecule compound; and in some cases, the small molecule compound has a molecular weight of less than 2,000. In some cases, the small molecule compound for the hole injection layer is deposited by evaporation techniques, such as vacuum thermal evaporation.

In some cases, the hole injection layer comprises a hole injection material that is not water-soluble. The use of water-soluble materials (such as PEDOT) deposited in an aqueous solution for the hole injection layer may be particularly unsuitable for phosphorescent OLEDs (in comparison to fluorescent OLEDs), in which the phosphorescent emissive layer is particularly vulnerable to damage by residual water or moisture that may be present. Thus, in some cases, the hole injection material is soluble in an organic solvent and is deposited by solution processing in an organic solvent.

In some cases, the hole injection layer comprises a cross-linked hole injection material, such as the cross-linked organometallic complexes described in US 2008/0220265, which is incorporated by reference herein. In such cases, the cross-linked hole injection layer may be made by depositing a solution containing a cross-linkable hole injection material and cross-linking the material, as described in US 2008/0220265. The cross-linked hole injection layer may further comprise a conducting dopant, such as that described in US 2008/0220265. A hole injection layer formed of a covalently cross-linked matrix can be useful in the fabrication of organic devices by solution processing techniques. In a multi-layered structure, any underlying layer is preferably resistant to the solvent that is being deposited upon it. This may allow the charge transport layer of the present invention to be deposited by solution deposition on the hole injection layer without the hole injection layer being dissolved, morphologically influenced, or degraded by a solvent that is deposited over it.

In embodiments where the device is an OLED, the OLED may be a fluorescent or phosphorescent emitting device. In some embodiments, devices of the present invention are phosphorescent OLEDs having an emissive layer that comprises a host material and a phosphorescent dopant material. In some embodiments, devices of the present invention are fluorescent OLEDs having an emissive layer that comprises a fluorescent emitting compound (such as a blue fluorescent emitting compound). In some embodiments, devices of the present invention include an electron transport layer between the emissive layer and the cathode.

In some embodiments, the charge transport layer of the present invention has two or more additive charge transport compounds. For example, the charge transport layer may have a small molecule additive and a polymer compound additive.

### EXPERIMENTAL

Specific representative embodiments of the invention will now be described, including how such embodiments may be made. It is understood that the specific methods, materials, conditions, process parameters, apparatus and the like do not necessarily limit the scope of the invention.

Example organic light-emitting devices were fabricated using spin-coating and vacuum thermal evaporation of the compounds shown below. The devices were fabricated on a glass substrate precoated with indium tin oxide (ITO) as the anode. The cathode was a layer of LiF followed by a layer of aluminum. The devices were encapsulated with a glass lid sealed with an epoxy resin under nitrogen (<1 ppm H₂O and O₂) immediately after fabrication.

Example Device 1 was made as a control and example Device 2 was made as the experimental device. In both of Devices 1 and 2, the hole injecting material HIL-1 along with Conducting dopant-1 were dissolved in cyclohexanone solvent. The amount of Conducting dopant-1 in the solution was 10 wt % relative to HIL-1. The total combined concentration of HIL-1 and Conducting dopant-1 was 0.5 wt % in cyclohexanone. To form the hole injection layer (HIL), the solution was spin-coated at 4000 rpm for 60 seconds onto the patterned indium tin oxide (ITO) electrode. The resulting film was baked for 30 minutes at 250° C., which rendered the film insoluble. For both devices, on top of the HIL, a hole transporting layer (HTL) and then an emissive layer (EML) were also formed by spin-coating.

For Device 1, the HTL was made by spin-coating a 0.5 wt % solution of the hole transporting material HTL-1 in toluene at 4000 rpm for 60 seconds. The HTL film was baked at 200° C. for 30 minutes. After baking, the HTL became an insoluble film. For Device 2, the HTL solution was made of HTL-1 plus NPD in toluene, with a total combined concentration of 0.5 wt %. The amount of NPD was 20 wt % relative to HTL-1, or 80:20 ratio of HTL-1:NPD.

For both devices, the EML was formed using a toluene solution containing Host-1, Host-2, and Green Dopant-1 at a total combined concentration of 0.75 wt %, with Host-1:Host-2:Green Dopant-1 weight ratio of 68:20:12. The solution was spin-coated on top of the insoluble HTL at 1000 rpm for 60 seconds, and then baked at 80° C. for 60 minutes to remove solvent residues. A 50 Å hole blocking layer containing Host-2, an electron transport layer containing LG201 (available from LG Chemical Corp.), an electron injection layer containing LiF, and an aluminum electrode (cathode) were sequentially vacuum deposited in a conventional fashion.

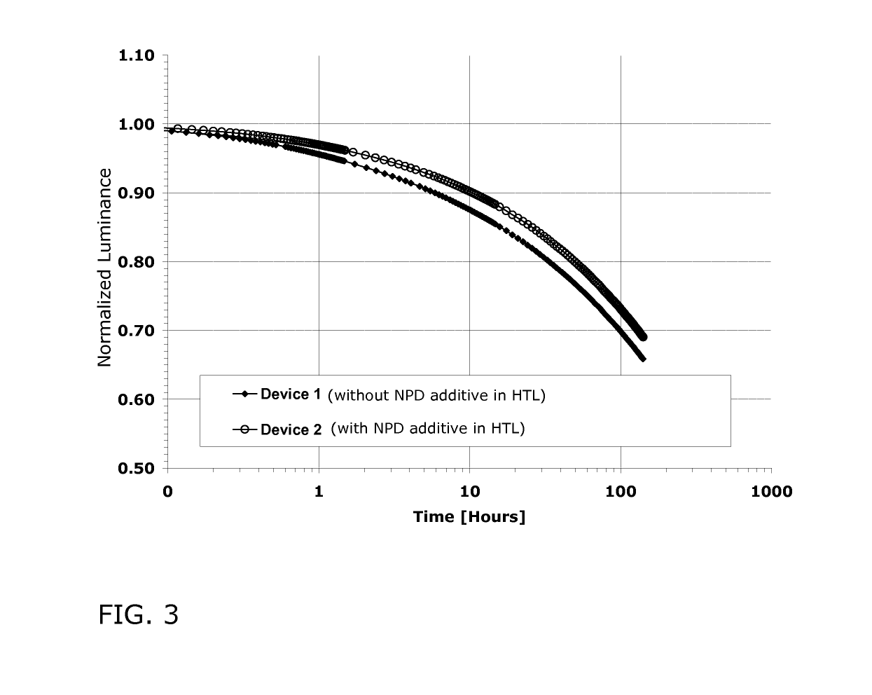

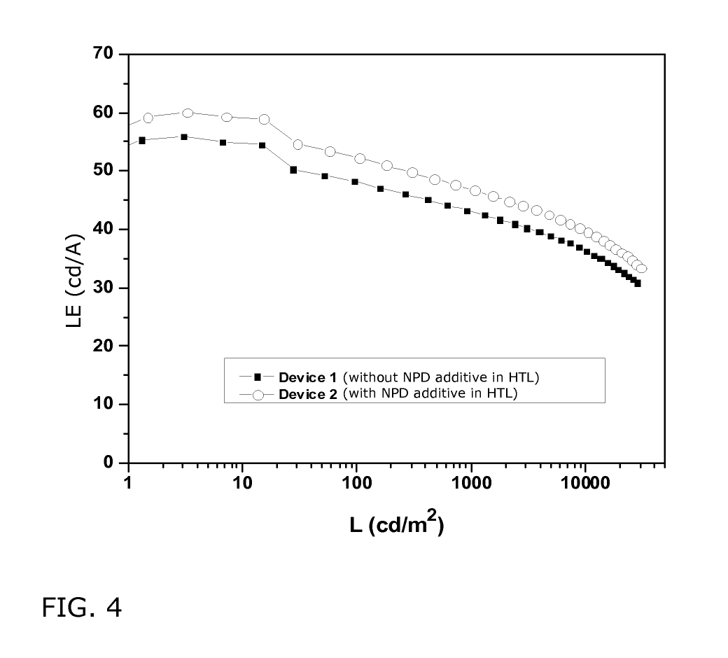

The performances of the devices were tested by operation under a constant DC current. FIG. 3 shows a plot of normalized luminance versus time for the devices. FIG. 4 shows a plot of luminance efficiency as a function of luminance for example Devices 1 and 2. Table 4 below summarizes the performance of the devices.

TABLE 4

| | Device 1 | |
|---|---|---|
| | (control) | Device 2 |
| Volts @ 1,000 cd/m² | 6.5 | 6.2 |
| LE (cd/A) @ 1,000 cd/m² | 42.8 | 47.0 |
| LT₇₀ (hours) @ 8,000 cd/m² | 99 | 131 |
| CIE (x, y) | (0.33, 0.63) | (0.33, 0.63) |

The lifetime LT₇₀ (as measured by the time elapsed for decay of brightness to 70% of the initial level) were 99 hours for Device 1 and 131 hours for Device 2 at a starting brightness of 8,000 cd/m². Device 2 with the NPD additive in the HTL had 30% longer lifetime than the control Device 1 without the NPD additive in the HTL. Moreover, as seen in Table 4, Device 2 with the NPD additive required a lower operating voltage (6.2 V) compared to control Device 1 (6.5 V), indicating that the hole mobility through the NPD-added HTL of Device 2 was better than the hole mobility through the HTL (no additive) of Device 1. Moreover, as seen in Table 4, Device 2 operated with better luminance efficiency than control Device 1.

One of the other notable results of this experiment is that NPD was deposited by solution processing to form the HTL. NPD is a commonly used hole transport compound, but is typically deposited by vacuum thermal evaporation because it has relatively low solubility. But by using the method of the present invention, solution deposition of NPD was made feasible and resulted in the construction of a device having superior performance.

### Materials Used for Making the Devices:

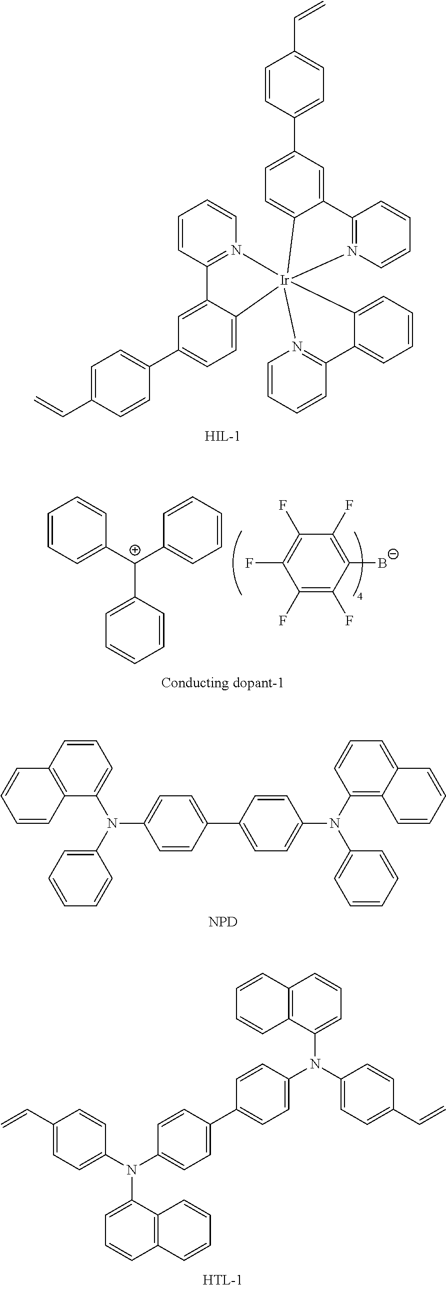

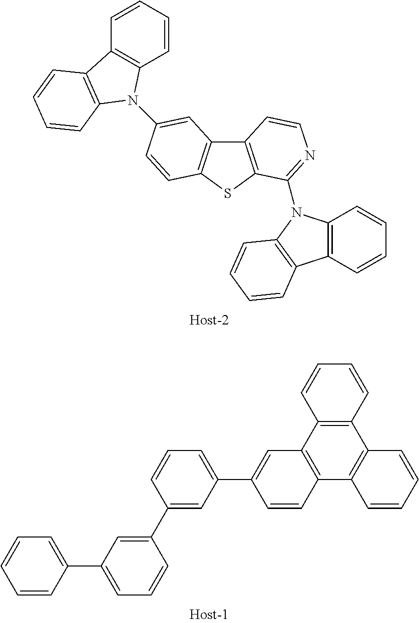

Green Dopant-1 is a mixture of compounds A, B, C, and D in a ratio of 1.9:18.0:46.7:32.8, as shown below.

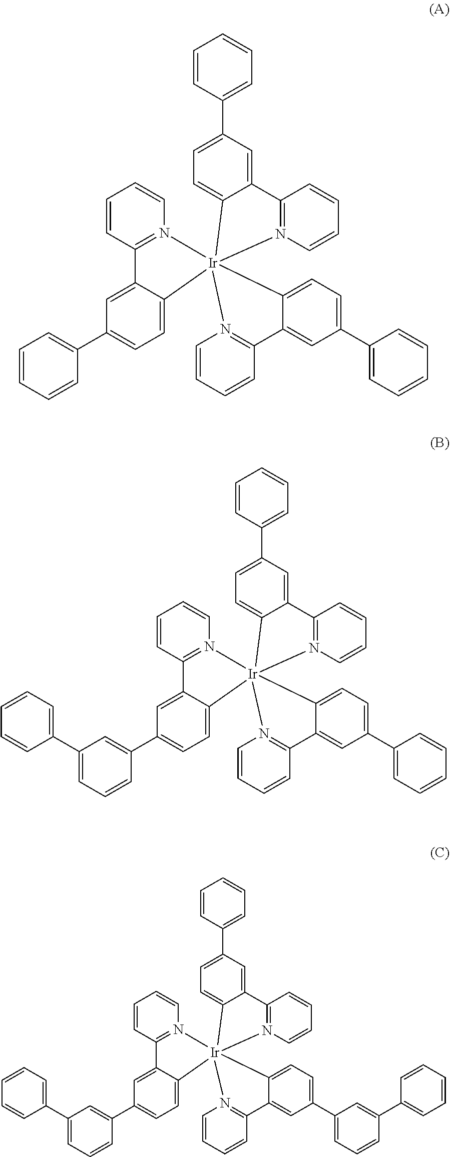

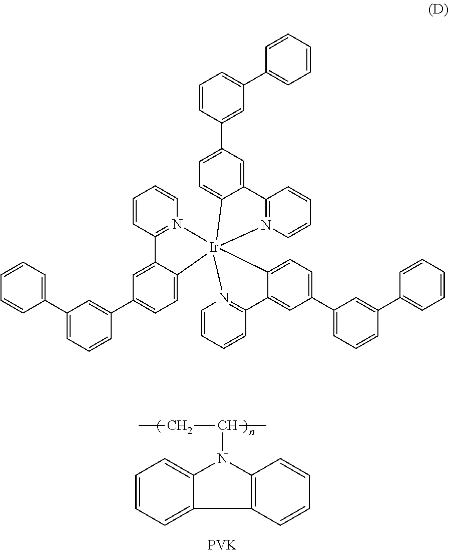

Example organic light-emitting devices were also made with the cross-linked hole transport layer containing a polymer additive as the second charge transport compound. The devices were fabricated using spin-coating and vacuum thermal evaporation of the compounds shown above. The devices were fabricated on a glass substrate precoated with indium tin oxide (ITO) as the anode. The cathode was a layer of LiF followed by a layer of aluminum. The devices were encapsulated with a glass lid sealed with an epoxy resin under nitrogen (<1 ppm H₂O and O₂) immediately after fabrication.

Example Device 3 was made as a control and example Device 4 was made as the experimental device. In both of Devices 3 and 4, the hole injecting material HIL-1 along with Conducting Dopant-1 (both shown above) were dissolved in cyclohexanone solvent. The amount of Conducting Dopant-1 in the solution was 10 wt % relative to HIL-1. The total combined concentration of HIL-1 and Conducting Dopant-1 was 0.5 wt % in cyclohexanone. To form the hole injection layer (HIL), the solution was spin-coated at 4000 rpm for 60 seconds onto the patterned indium tin oxide (ITO) electrode. The resulting film was baked for 30 minutes at 250° C., which rendered the film insoluble. For both devices, on top of the HIL, a hole transporting layer (HTL) and then an emissive layer (EML) were also formed by spin-coating.

For control Device 3, the HTL was made by spin-coating a 0.5 wt % solution of the hole transporting material HTL-1 (shown above) in toluene at 4000 rpm for 60 seconds. The HTL film was baked at 200° C. for 30 minutes. After baking, the HTL became an insoluble film. For the experimental Device 4, the HTL solution was made of HTL-1 plus PVK (poly-N-vinylcarbazole) in chlorobenzene, with a total combined concentration of 0.5 wt %. The amount of PVK was 20 wt % relative to HTL-1, or 80:20 ratio of HTL-1:PVK.

For both devices, the EML was formed using a toluene solution containing Host-1, and Green Dopant-1 at a total combined concentration of 0.75 wt %, with Host-1:Green Dopant-1 weight ratio of 88:12 (compound structures shown above). The solution was spin-coated on top of the insoluble HTL at 1000 rpm for 60 seconds, and then baked at 80° C. for 60 minutes to remove solvent residues. A 50 Å hole blocking layer containing Host-2, an electron transport layer containing LG201 (available from LG Chemical Corp.), an electron injection layer containing LiF, and an aluminum electrode (cathode) were sequentially vacuum deposited in a conventional fashion.

Table 5 below summarizes the performance data for control Device 3 (without any additive in the cross-linked HTL) and Device 4 (with the polymer PVK additive in the cross-linked HTL). The lifetime LT₈₀ (as measured by the time elapsed for decay of brightness to 80% of the initial level) were 89 hours for Device 3 and 164 hours for Device 4 at a starting brightness of 8,000 cd/m². According to this result, Device 4 with the PVK additive in the HTL had about 80% longer lifetime than the control Device 3 without the PVK additive in the HTL. As seen in Table 5, Device 4 with the PVK additive required a slightly higher voltage (6.3 V) compared to control Device 3 (6.1 V).

TABLE 5
Summary of device performance (single additive)

| | Device 3 | Device 4 |
|---|---|---|
| | (control) | (PVK additive) |
| Volts @ 1,000 cd/m² | 6.1 | 6.3 |
| LE (cd/A) @ 1,000 cd/m² | 51 | 46.5 |
| LT₈₀ (hours) @ 8,000 cd/m² | 89 | 164 |
| CIE (x, y) | (0.32, 0.63) | (0.32, 0.63) |

Example organic light-emitting devices were also made with the cross-linked hole transport layer containing both a small molecule charge transport compound and a polymer charge transport compound as additives. For example Devices 5 and 6, the anode, the cathode, and the hole injection layer were made in the same manner as described above for Devices 3 and 4. For Device 5, the HTL was made by spin-coating a 0.5 wt % solution of the hole transporting material HTL-1 in chlorobenzene at 4000 rpm for 60 seconds. The HTL film was baked at 200° C. for 30 minutes. After baking, the HTL became an insoluble film. For Device 6, the HTL solution was made of HTL-1, plus the small molecule compound NPD and the polymer compound PVK in chlorobenzene as additives, with a total combined concentration of 0.5 wt %. The weight ratio of HTL-1:NPD:PVK was 70:10:20.

FIG. 7 shows a plot of luminance (normalized) versus time for the devices. Table 6 below summarizes the performance data for control Device 5 (without any additive in the cross-linked HTL) and Device 6 (with both NPD and PVK as additives in the cross-linked HTL). The lifetime LT₈₀ (as measured by the time elapsed for decay of brightness to 80% of the initial level) were 100 hours for Device 5 and 130 hours for Device 6 at a starting brightness of 8,000 cd/m². According to this result, Device 6 with the NPD and PVK additives in the HTL had about 30% longer lifetime than the control Device 5 without any additive in the HTL. As seen in Table 6, Device 6 with the NPD and PVK additives required the same voltage (5.9 V) and had similar efficiency (˜41.5 cd/A) compared to control Device 5.

TABLE 6
Summary of device performance (dual additive)

| | Device 5 | Device 6 |
|---|---|---|
| | (control) | (NPD + PVK) |
| Volts @ 1,000 cd/m² | 5.9 | 5.9 |
| LE (cd/A) @ 1,000 cd/m² | 41.8 | 41.3 |
| LT₉₀ (hours) @ 8,000 cd/m² | 100 | 130 |
| CIE (x, y) | (0.32, 0.63) | (0.32, 0.63) |

It is understood that the various embodiments described herein are by way of example only, and are not intended to limit the scope of the invention. For example, many of the materials and structures described herein may be substituted with other materials and structures without deviating from the spirit of the invention. It is understood that various theories as to why the invention works are not intended to be limiting. For example, theories relating to charge transfer are not intended to be limiting.

### Material Definitions:

As used herein, abbreviations refer to materials as follows:
CBP: 4,4′-N,N-dicarbazole-biphenyl
m-MTDATA 4,4′,4″-tris(3-methylphenylphenlyamino)triphenylamine
Alq₃: aluminum(III) tris(8-hydroxyquinoline)
Bphen: 4,7-diphenyl-1,10-phenanthroline
n-BPhen: n-doped BPhen (doped with lithium)
F₄-TCNO: tetrafluoro-tetracyano-quinodimethane
p-MTDATA: p-doped m-MTDATA (doped with F₄-TCNQ)
Ir(ppy)₃: tris(2-phenylpyridine)-iridium
Ir(ppz)₃: tris(1-phenylpyrazoloto,N,C(2′)iridium(III)
BCP: 2,9-dimethyl-4,7-diphenyl-1,10-phenanthroline
TAZ: 3-phenyl-4-(1′-naphthyl)-5-phenyl-1,2,4-triazole
CuPc: copper phthalocyanine.
ITO: indium tin oxide
NPD: N,N′-diphenyl-N—N′-di(1-naphthyl)-benzidine
TPD: N,N′-diphenyl-N—N′-di(3-toly)-benzidine
BAlq: aluminum(III)bis(2-methyl-8-hydroxyquinolinato)4-phenylphenolate
mCP: 1,3-N,N-dicarbazole-benzene
DCM: 4-(dicyanoethylene)-6-(4-dimethylaminostyryl-2-methyl)-4H-pyran
DMQA: N,N′-dimethylquinacridone
PEDOT:PSS: an aqueous dispersion of poly(3,4-ethylenedioxythiophene) with polystyrenesulfonate (PSS)

We claim:

1. An organic electronic device comprising:
a first electrode;
a second electrode; and
a charge transport layer between the first electrode and the second electrode, the charge transport layer comprising:
(a) a covalently cross-linked host matrix comprising a first organic charge transport compound as molecular subunits of the cross-linked host matrix; and
(b) a second organic charge transport compound that is a polymer compound that transports the same type of charge as the cross-linked host matrix.

2. The device of claim 1, wherein the first charge transport compound and the second charge transport compound are both hole transport compounds.

3. The device of claim 2, wherein the charge transport layer is a hole transport layer.

4. The device of claim 1, wherein the polymer compound includes triarylamine moieties.

5. The device of claim 1, wherein the polymer compound includes carbazole moieties.

6. The device of claim 1, wherein the device is an organic light-emitting device that further comprises an emissive layer between the charge transport layer and the second electrode.

7. The device of claim 6, wherein the emissive layer comprises a phosphorescent emitting dopant.

8. The device of claim 6, wherein the emissive layer comprises a fluorescent emitting compound.

9. The device of claim 1, wherein the charge transport layer further comprises a third organic charge transport compound that is a small molecule compound that transports the same type of charge as the cross-linked host matrix.

10. The device of claim 1, wherein the charge transport layer is an electron transport layer.

11. An organic electronic device comprising:
a first electrode;
a second electrode;
a hole transport layer between the first electrode and the second electrode, the hole transport layer comprising:
(a) a covalently cross-linked host matrix comprising a first organic hole transport compound as molecular subunits of the cross-linked host matrix; and
(b) a second organic hole transport compound that transports the same type of charge as the cross-linked host matrix.

12. The device of claim 11, wherein the second hole transport compound is a small molecule compound.

13. The device of claim 11, wherein the second hole transport compound is a polymer compound.

14. The device of claim 11, wherein the second hole transport compound has a higher hole mobility than the cross-linked host matrix or the first hole transport compound.

15. The device of claim 11, wherein the second hole transport compound includes triarylamine moieties.

16. The device of claim 11, wherein the first hole transport compound is an arylamine compound.

17. The device of claim 11, wherein the hole transport layer is made by the deposition of an organic solution containing the first hole transport compound and the second hole transport compound.

18. The device of claim 11, wherein the device is an organic light-emitting device and further comprises an emissive layer between the charge transport layer and the second electrode.

19. The device of claim 18, wherein the emissive layer comprises a phosphorescent emitting dopant.

20. The device of claim 18, wherein the emissive layer comprises a fluorescent emitting compound.

21. A method of making an organic electronic device, comprising:
providing a first electrode disposed over a substrate;
depositing over the first electrode, a solution comprising: (a) a first organic charge transport compound having one or more cross-linkable reactive groups, and (b) a second organic charge transport compound that transports the same type of charge as the first charge transport compound;
forming a first organic layer by cross-linking the first charge transport compound;
forming a second organic layer over the first organic layer; and
forming a second electrode over the second organic layer.

22. A liquid composition comprising:
a solvent;
a first organic charge transport compound having one or more cross-linkable reactive groups; and
a second organic charge transport compound that transports the same type of charge as the first charge transport compound.
